(19) United States
(12) Patent Application Publication
(10) Pub. No.: US 2026/0060028 A1
(43) Pub. Date: Feb. 26, 2026

(54) SUBSTRATE PROCESSING APPARATUS

(71) Applicant: SCREEN Holdings Co., Ltd., Kyoto (JP)

(72) Inventor: Tadashi MAEGAWA, Kyoto (JP)

(21) Appl. No.: 19/105,773

(22) PCT Filed: Jun. 7, 2023
(86) PCT No.: PCT/JP2023/021214

§ 371 Date: Feb. 21, 2025

(30) Foreign Application Priority Data
Aug. 23, 2022 (JP) 2022-132491

(51) Int. Cl. H01L 21/67; B08B 3/08; B25J 11/00; H01L 21/677

(52) U.S. Cl. CPC H01L 21/67057; B08B 3/08; H01L 21/67167; H01L 21/67196; H01L 21/67718; B25J 11/0095

(57) ABSTRACT

There is provided a substrate processing apparatus with improved throughput by reconsidering a configuration of an apparatus including a batch type module and a single wafer type module. In a single wafer processing region according to single wafer processing of a processing block of the present invention, a buffer unit to and from which both a first transfer mechanism HTR and a center robot can hand over and receive a substrate(s) is provided. Therefore, the first transfer mechanism can collectively hand over and receive processed substrates and unprocessed substrates via the buffer unit. Therefore, a potential of the first transfer mechanism is drawn out, and the substrate processing apparatus having a high throughput can be provided.

### TECHNICAL FIELD

The present invention relates to a substrate processing apparatus that performs predetermined processing on various substrates such as a semiconductor substrate, a substrate for a flat panel display (FPD) such as a liquid crystal display or an organic electroluminescence (EL) display device, a glass substrate for a photomask, and a substrate for an optical disk.

### BACKGROUND ART

Conventionally, this type of apparatus includes a batch type module and a single wafer type module (see, for example, Patent Literature 1). The batch type module collectively performs predetermined processing on a plurality of substrates. The single wafer type module performs predetermined processing on each substrate. Each of the batch type module and the single wafer type module has unique advantages. For example, the single wafer type module has higher particle performance in drying treatment than the batch type module. Therefore, as an apparatus including a batch type module or a single wafer type module, a configuration is conceivable in which liquid treatment is performed in the batch type module, and then drying treatment is performed in the single wafer type module.

In the apparatus of Patent Literature 1, the substrates processed by the batch type module and the single wafer type module are returned one by one to a cassette. That is, according to the conventional configuration, the substrate processed by the single wafer type module is received by a robot that transfers the substrate one by one, and is stacked on the cassette. That is, the apparatus of Patent Literature 1 has a configuration in which processed substrates are returned to the cassette one by one by a transfer method similar to a substrate processing apparatus that does not have a batch type module and performs substrate processing by a single wafer type module.

### CITATION LIST

### Patent Literature

Patent Literature 1: JP 2016-502275 A

### SUMMARY OF INVENTION

### Technical Problem

However, the conventional apparatus having such a configuration has the following problems.

That is, according to the conventional configuration, a high throughput cannot be obtained. As a substrate processing apparatus having a batch type module, there is a substrate processing apparatus having a substrate handling mechanism for collectively taking out a plurality of substrates arranged in a cassette. Such a substrate handling mechanism does not need to transfer a single substrate one by one, and greatly contributes to improvement of throughput. Certainly, the apparatus configuration having the substrate handling mechanism is advantageous in that unprocessed substrates are collectively taken out from the cassette. However, in the conventional apparatus configuration, the processed substrates to be carried out from the single wafer type module are returned to the cassette one by one. Therefore, the advantage of the substrate handling mechanism is not utilized at the stage where the processed substrate is returned to the cassette.

Further, such a problem does not occur only in the above-described substrate processing apparatus. A similar problem also occurs in a substrate processing apparatus in reverse order in which substrate processing is performed in the order of the single wafer type module and the batch type module. In the substrate transfer method in the apparatus in reverse order, the flow of the substrate is reverse to the substrate transfer method in the above-described apparatus (apparatus in normal order) that performs processing in order of the batch type module and the single wafer type module. Therefore, the apparatus in reverse order having the collective substrate handling mechanism is advantageous in that the processed substrates are collectively returned to the cassette. However, in the conventional apparatus configuration, the unprocessed substrates are transferred one by one from the cassette to the single wafer type module. That is, in the apparatus in reverse order, the advantage of the substrate handling mechanism is not utilized at the stage where the unprocessed substrate is taken out from the cassette.

The present invention has been made in view of such circumstances, and it is an object of the present invention to provide a substrate processing apparatus with improved throughput by reviewing a configuration of an apparatus including a batch type module and a single wafer type module.

### Solution to Problem

In order to achieve such an object, the present invention has the following configuration.

A substrate processing apparatus that continuously performs batch processing of collectively processing a plurality of substrates and single wafer processing of processing substrates one by one, the substrate processing apparatus including a stocker block, a transfer block adjacent to the stocker block, and a processing block adjacent to the transfer block, in which the stocker block accommodates at least one carrier that stores a plurality of substrates in a horizontal attitude at predetermined intervals in a vertical direction, the stocker block including a carrier mounting shelf for taking out and storing at least one substrate on which the carrier is mounted for taking in and out the substrates from the carrier, and the transfer block includes a substrate handling mechanism that collectively takes out and stores a plurality of substrates with respect to the carrier mounted on the carrier mounting shelf, and a first attitude changing mechanism that collectively changes an attitude of a plurality of substrates between a horizontal attitude and a vertical attitude, the processing block includes a batch processing region having one end side adjacent to the transfer block and another end side extending in a direction away from the transfer block, a single wafer processing region having one end side adjacent to the transfer block and another end side extending in the direction away from the transfer block, a single substrate transfer region interposed between the batch processing region and the single wafer processing region, and having one end adjacent to the transfer block and another end side extending in the direction away from the transfer block, and a batch substrate transfer region provided along the batch processing region, and having one end side extending to the transfer block and another end side extending in the direction away from the transfer block, and in the batch processing region, a plurality of batch processing tanks that collectively subjects a plurality of substrates to an immersion treatment is arranged in a direction in which the region extends, and a second attitude changing mechanism that collectively changes an attitude of the plurality of substrates between a vertical attitude and a horizontal attitude is provided at a position farthest from the transfer block, in the single wafer processing region, a plurality of single wafer processing chambers that processes substrates one by one is arranged in a direction in which the region extends, and a substrate mounting unit that mounts a plurality of substrates in a horizontal attitude at same predetermined intervals as the predetermined intervals of the carrier in a vertical direction is provided at a position closest to the transfer block, in the single substrate transfer region, a single substrate transfer mechanism that transfers a substrate among the second attitude changing mechanism, the single wafer processing chamber, and the substrate mounting unit is provided, in the batch substrate transfer region, a batch substrate transfer mechanism that collectively transfers a plurality of substrates among a substrate handover position defined in the transfer block, the batch processing tanks, and the second attitude changing mechanism is provided, and the substrate handling mechanism of the transfer block is further configured to be able to collectively transfer a plurality of substrates to and from the substrate mounting unit in the single wafer processing region.

### [Operation and Effect]

According to the invention according to (1) described above, the substrate mounting unit to and from which both the substrate handling mechanism and the single substrate transfer mechanism can hand over and receive a substrate is provided in the single wafer processing region. Therefore, the substrate handling mechanism can collectively hand over and receive the substrate(s) between the single wafer processing regions via the substrate mounting unit. Specifically, in the apparatus in normal order described above, the substrates subjected to the single wafer processing, which are dispensed one by one by the single substrate transfer mechanism, are arranged and stocked in the vertical direction in the substrate mounting unit. The substrate handling mechanism collectively stores the plurality of substrates stocked on the substrate mounting unit in the carrier. In the apparatus in normal order, the substrate handling mechanism collectively takes out unprocessed substrates from the carrier similarly to the conventional configuration. On the other hand, in the apparatus in reverse order, unprocessed substrates collectively brought into the single wafer processing region by the substrate handling mechanism are arranged and stocked in the vertical direction in the substrate mounting unit. The single substrate transfer mechanism transfers the plurality of substrates stocked in the substrate mounting unit one by one to the single wafer processing chamber. In the apparatus in reverse order, the substrate handling mechanism collectively stores the processed substrates in the carrier similarly to the conventional configuration. Therefore, in any apparatus configuration, the substrates are collectively taken in and out of the carrier by the substrate handling mechanism. With this configuration, a potential of the substrate handling mechanism is drawn out, and a substrate processing apparatus having a high throughput can be provided.

Further, according to the invention according to (1) described above, one end of each of the batch processing region, the single wafer processing region, the single substrate transfer region, and the batch substrate transfer region is adjacent to the transfer block. Therefore, the transfer distance of the substrate is shortened between the transfer block and the batch processing region and between the transfer block and the single wafer processing region, and the substrate can be smoothly transferred therebetween. The present invention also has the following features.

(2) In the substrate processing apparatus according to (1), the batch processing region includes a batch chemical solution treatment tank that stores a chemical solution for collectively performing a chemical solution treatment on a plurality of substrates, and a batch rinse treatment tank that stores a rinse solution for collectively performing a rinse treatment on a plurality of substrates subjected to the chemical solution treatment, the batch chemical solution treatment tank is located closer to the transfer block than the batch rinse treatment tank, the single wafer processing region includes a single wafer liquid treatment chamber for liquid treatment of substrates one by one, and a single wafer drying treatment chamber for drying the substrates subjected to liquid treatment one by one, and the single wafer drying treatment chamber is located closer to the transfer block than the single wafer liquid treatment chamber, in the transfer block, the substrate handling mechanism collectively takes out a plurality of substrates from the carrier, and the first attitude changing mechanism changes an attitude of the plurality of substrates taken out from a horizontal attitude to a vertical attitude, in the processing block, the batch substrate transfer mechanism collectively receives a plurality of substrates in a vertical attitude at the substrate handover position of the transfer block and transfers the received plurality of substrates to the batch chemical solution treatment tank, the batch rinse treatment tank, and the second attitude changing mechanism in this order, the second attitude changing mechanism changes an attitude of the received plurality of substrates in the vertical attitude to a horizontal attitude, and the single substrate transfer mechanism transfers the substrates changed to the horizontal attitude by the second attitude changing mechanism one by one to the single wafer liquid treatment chamber, the single wafer drying treatment chamber, and the substrate mounting unit in this order, and in the transfer block, when a plurality of substrates is mounted on the substrate mounting unit in the processing block, the substrate handling mechanism collectively takes out the plurality of substrates from the substrate mounting unit and collectively stores the plurality of substrates taken out in the carrier.

### [Operation and Effect]

With the configuration according to (2), the plurality of substrates is subjected to the chemical solution treatment in the batch chemical solution treatment tank close to the transfer block in the batch processing region. Thereafter, the plurality of substrates is subjected to the rinse treatment in the batch rinse treatment tank away from the transfer block in the batch processing region. After the rinse treatment, the plurality of substrates is changed from the vertical attitude to the horizontal attitude by the second attitude changing mechanism farthest from the transfer block. The plurality of substrates in the horizontal attitude is in a standby state for single wafer processing. As described above, according to the configuration of (2), the respective processes of the chemical solution treatment, the batch rinse treatment, and the attitude changing are sequentially executed as the plurality of substrates is transferred in the direction away from the transfer block. Therefore, according to the present invention, it is possible to achieve a substrate processing apparatus having a short substrate transfer distance in a batch processing region and a high throughput.

Further, with the configuration according to (2), the substrates changed to the horizontal attitude are subjected to liquid treatment one by one in the single wafer liquid treatment chamber away from the transfer block in the single wafer processing region. Subsequently, substrates subjected to the drying treatment in the single wafer drying treatment chamber are stocked at the substrate mounting unit close to the transfer block in the batch processing region, and is in a standby state for collective transfer by the substrate handling mechanism. As described above, according to the configuration of (2), the respective processes of the liquid treatment, the drying treatment, and collective transfer standby are sequentially executed as the substrates are transferred one by one in the processing block in a direction approaching the transfer block. Therefore, according to the present invention, it is possible to achieve a substrate processing apparatus having a short substrate transfer distance in a single wafer processing region and a high throughput.

With the configuration according to (2), the substrate whose attitude has been changed to the horizontal attitude by the second attitude changing mechanism is disposed at a position close to the single wafer liquid treatment chamber. The single wafer liquid treatment chamber is located farther from the transfer block than the single wafer drying treatment chamber. This is because, since the second attitude changing mechanism is located at a position farthest from the transfer block, the single wafer liquid treatment chamber is located closer to the second attitude changing mechanism than the single wafer drying treatment chamber. With this configuration, the distance when the substrates are transferred one by one from the batch processing region to the single wafer processing region is shortened. Therefore, according to the configuration of (2), the throughput is high, and unexpected drying of the substrate is prevented. Further, the time until the substrate is carried out from the second attitude changing mechanism and carried into the single wafer liquid treatment chamber is shortened, and contamination of the substrate occurring during transfer can be prevented as much as possible.

(3) In the substrate processing apparatus according to (1), the single wafer processing region includes a single wafer liquid treatment chamber for liquid treatment of substrates one by one, the batch processing region includes a batch chemical solution treatment tank that stores a chemical solution for collectively performing a chemical solution treatment on a plurality of substrates, a batch rinse treatment tank that stores a rinse solution for collectively performing a rinse treatment on a plurality of substrates subjected to the chemical solution treatment, and a batch drying chamber that collectively performs a drying treatment of the plurality of substrates subjected to the rinse treatment, the batch drying chamber is located closer to the transfer block than the batch rinse treatment tank, the batch rinse treatment tank is located closer to the transfer block than the batch chemical solution treatment tank, in the transfer block, the substrate handling mechanism collectively takes out a plurality of substrates from the carrier and mounts the substrates on the substrate mounting unit in the processing block, in the processing block, the single substrate transfer mechanism transfers a plurality of substrates mounted on the substrate mounting unit one by one to the single wafer liquid treatment chamber and the second attitude changing mechanism in this order, the second attitude changing mechanism changes an attitude of a plurality of substrates in a horizontal attitude to a vertical attitude when the plurality of substrates in the horizontal attitude is received, and the batch substrate transfer mechanism collectively receives the plurality of substrates in the vertical attitude in the second attitude changing mechanism and transfers the received plurality of substrates to the batch chemical solution treatment tank, the batch rinse treatment tank, the batch drying chamber, and the substrate handover position in the transfer block, and in the transfer block, the first attitude changing mechanism changes an attitude of a plurality of substrates received at the substrate handover position from a vertical attitude to a horizontal attitude, and the substrate handling mechanism collectively stores the plurality of substrates in the horizontal attitude in the carrier.

### [Operation and Effect]

With the configuration according to (3), the plurality of substrates transferred from the transfer block to the processing block is first mounted on the substrate mounting unit in the horizontal attitude. Therefore, the plurality of substrates before the single wafer processing is stocked on a side closer to the transfer block of the processing block. Thereafter, the plurality of substrates is subjected to liquid treatment in the single wafer processing chamber one by one. At this time, the substrates are transferred one by one in the direction away from the transfer block. As described above, according to the configuration of (3), the process of liquid treatment is executed as one substrate is transferred in the processing block in the direction away from the transfer block. Therefore, according to the present invention, it is possible to achieve a substrate processing apparatus having a short substrate transfer distance in a single wafer processing region and a high throughput.

Further, with the configuration according to (3), each of the substrates in the horizontal attitude on which the liquid treatment by the single wafer processing chamber is completed is stocked in the second attitude changing mechanism farthest from the transfer block. Then, the plurality of substrates in the horizontal attitude is brought into the vertical attitude by the second attitude changing mechanism. The plurality of substrates in the vertical attitude is subjected to the chemical solution treatment in the batch chemical solution treatment tank away from the transfer block in the batch processing region. Thereafter, the plurality of substrates is subjected to the rinse treatment in the batch rinse treatment tank close to the transfer block in the batch processing region. After the rinse treatment, the plurality of substrates is subjected to the drying treatment in the batch drying chamber closest to the transfer block. As described above, according to the configuration of (3), the processes of the chemical solution treatment, the batch rinse treatment, and the batch drying treatment are sequentially executed as the plurality of substrates is transferred from the position farthest from the transfer block in the direction approaching the transfer block. Therefore, according to the present invention, it is possible to achieve a substrate processing apparatus having a short substrate transfer distance in a batch processing region and a high throughput.

(4) In the substrate processing apparatus according to (1), the single wafer drying treatment chamber dries the substrate with a supercritical fluid.

### [Operation and Effect]

With the configuration according to (4), the substrate processing can be executed in a state where the circuit pattern generated on the substrate is reliably retained.

(5) In the substrate processing apparatus according to (1), the single substrate transfer mechanism includes a first hand that transfers a substrate before the drying treatment, and a second hand that transfers a substrate after the drying treatment, the second hand being provided above the first hand.

### [Operation and Effect]

With the configuration according to (5), the substrate after the drying treatment is not wetted by the first hand, and a dry state of the substrate after the drying treatment can be reliably maintained.

(6) In the substrate processing apparatus according to (1), the single substrate transfer mechanism includes a first robot that transfers a substrate before the drying treatment, and a second robot that transfers a substrate after the drying treatment.

### [Operation and Effect]

With the configuration according to (6), since the robot that transfers the substrate after the drying treatment is provided separately from the robot that transfers the substrate before the drying treatment, the substrate before the drying treatment and the substrate after the drying treatment can be transferred simultaneously, so that the throughput of the substrate processing apparatus is improved. Further, since the robot that transfers the substrate after the drying treatment does not grip a wet substrate before the drying treatment, the robot that transfers the substrate after the drying treatment does not transfer the substrate after the drying treatment in a wet state. Therefore, with such a configuration, it is possible to provide a substrate processing apparatus that reliably maintains the dry state of the substrate.

### Advantageous Effects of Invention

According to the present invention, a substrate mounting unit to and from which both a substrate handling mechanism and a single substrate transfer mechanism can hand over and receive a substrate(s) is provided in a single wafer processing region. Therefore, the substrate handling mechanism can collectively hand over and receive substrates to and from the single wafer processing region via the substrate mounting unit. With this configuration, substrates are collectively taken in and out of a carrier by the substrate handling mechanism. Therefore, the potential of the substrate handling mechanism is drawn out, and a substrate processing apparatus having a high throughput can be provided. Further, according to the present invention, in a batch processing region in the processing block, a second attitude changing mechanism is disposed at a position farther from a transfer block than a processing tank or the like that performs predetermined processing on the substrates, and thus, in the apparatus in normal order, a plurality of substrates subjected to batch processing is transferred in a direction away from the transfer block when moving toward the second attitude changing mechanism. Then, the plurality of substrates whose attitude has been changed by the second attitude changing mechanism is transferred in a direction approaching the transfer block when single wafer processing is performed. As described above, in the apparatus in normal order, substrates are transferred so as to be away from the transfer block and subjected to batch processing in the processing block, and then transferred so as to approach the transfer block and subjected to single wafer processing, whereby the series of processing on the substrates is completed. Further, in the apparatus in reverse order, a plurality of substrates subjected to the single wafer processing is transferred in the direction away from the transfer block when being transferred toward the second attitude changing mechanism. Then, the plurality of substrates whose attitude has been changed by the second attitude changing mechanism is transferred in the direction approaching the transfer block when batch processing is performed. As described above, in the apparatus in reverse order, the substrates are transferred so as to approach the transfer block after being moved away from the transfer block once in the processing block, whereby the series of processing on the substrates is completed. In any of the apparatuses, it is necessary to reciprocate the substrates only once, and it is possible to provide a substrate processing apparatus having a short substrate transfer distance and a high throughput.

### BRIEF DESCRIPTION OF DRAWINGS

FIG. 1 is a plan view describing an overall configuration of a substrate processing apparatus according to a first embodiment.

FIG. 2 is a perspective view specifically describing an attitude changing unit.

FIG. 3 is a schematic view illustrating operation of the attitude changing unit.

FIG. 4 is a flowchart describing a flow of substrate processing.

FIG. 5 is a schematic view illustrating a flow of the substrate processing.

FIG. 6 is a schematic view illustrating a flow of the substrate processing.

FIG. 7 is a schematic view illustrating a flow of the substrate processing.

FIG. 8 is a schematic view illustrating a flow of the substrate processing.

FIG. 9 is a plan view describing an overall configuration of a substrate processing apparatus according to a second embodiment.

FIG. 10 is a flowchart describing a flow of substrate processing.

FIG. 11 is a schematic view illustrating a flow of the substrate processing.

FIG. 12 is a schematic view illustrating a flow of the substrate processing.

FIG. 13 is a schematic view illustrating a flow of the substrate processing.

FIG. 14 is a schematic view illustrating a flow of the substrate processing.

FIG. 15 is a schematic view illustrating a flow of the substrate processing.

FIG. 16 is a schematic view illustrating a modification of the present invention.

FIG. 17 is a plan view describing a modification of the present invention.

### DESCRIPTION OF EMBODIMENTS

Hereinafter, embodiments of the present invention will be described with reference to the drawings. The substrate processing apparatus of the present invention is an apparatus that continuously performs batch processing of collectively processing a plurality of substrates W and single wafer processing of processing the substrates W one by one.

### First Embodiment

### <1. Overall Configuration>

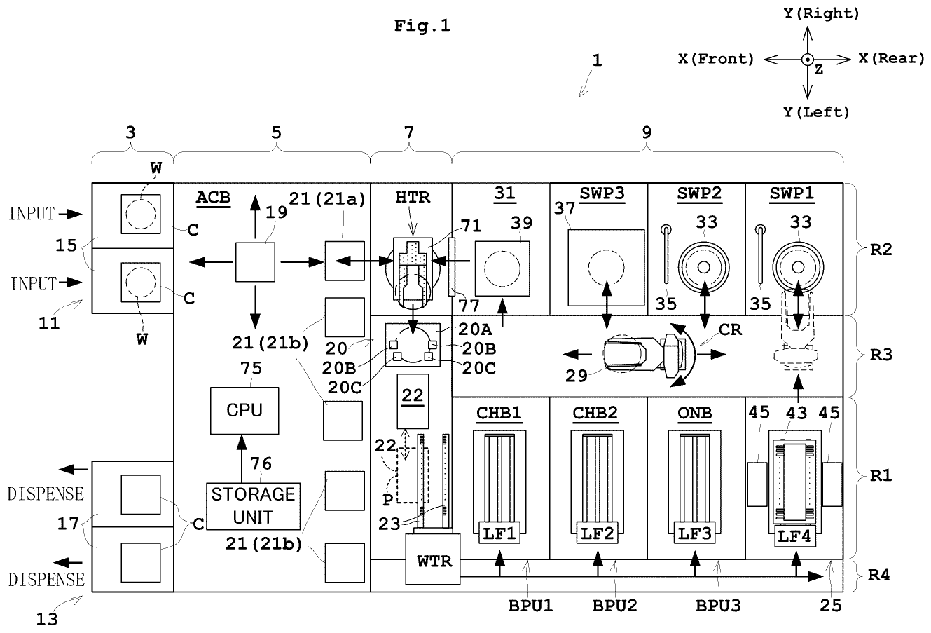

As illustrated in FIG. 1, the substrate processing apparatus 1 includes blocks defined by partition walls. That is, the substrate processing apparatus 1 includes a carry-in/out block 3, a stocker block 5 adjacent to the carry-in/out block 3, a transfer block 7 adjacent to the stocker block 5, and a processing block 9 adjacent to the transfer block 7. The stocker block 5 corresponds to a stocker block of the present invention, the transfer block 7 corresponds to a transfer block of the present invention, and the processing block 9 corresponds to a processing block of the present invention.

The substrate processing apparatus 1 performs, for example, each treatment such as chemical solution treatment, cleaning treatment, and drying treatment on the substrates W. The substrate processing apparatus 1 employs a processing method (what is called a hybrid method) in which both a batch type processing method of collectively processing a plurality of substrates W and a single wafer type processing method of processing substrates W one by one are used in combination. The batch type processing method is a processing method for collectively processing a plurality of substrates W arranged in a vertical attitude. The single wafer processing method is a processing method of processing the substrates W in a horizontal attitude one by one.

In the present specification, for convenience, a direction in which the carry-in/out block 3, the stocker block 5, the transfer block 7, and the processing block 9 are arranged is referred to as a “front-rear direction X”. The front-rear direction X extends horizontally. Of the front-rear direction X, the direction from the stocker block 5 toward the carry-in/out block 3 is referred to as “front”. A direction opposite to the front is referred to as “rear”. A direction extending horizontally orthogonal to the front-rear direction X is referred to as a “width direction Y”. One direction of the “width direction Y” is referred to as a “right side” for convenience, and the other direction is referred to as a “left side” for convenience. A direction (height direction) orthogonal to the front-rear direction X and the width direction Y is referred to as a “vertical direction Z” for convenience. In each drawing, front, back, right, left, top, and bottom are appropriately indicated for reference.

### <2. Carry-In/Out Block>

The carry-in/out block 3 includes an input unit 11 that is an entrance when a carrier C storing the plurality of substrates W in the vertical direction at predetermined intervals in the horizontal attitude is input to the block, and a dispensing unit 13 that is an exit when the carrier C is dispensed out of the block. The input unit 11 and the dispensing unit 13 are provided on an outer wall of the carry-in/out block 3 extending in the width direction (Y direction). The input unit 11 is provided on the right side as viewed from the central portion in the width direction (Y direction) in the substrate processing apparatus 1, and the dispensing unit 13 is provided on the left side opposite to the right side as viewed from the central portion in the width direction (Y direction) in the substrate processing apparatus 1.

The plurality of (for example, 25) substrates W is stacked and stored in one carrier C at regular intervals in the horizontal attitude. The carrier C storing unprocessed substrate W carried into the substrate processing apparatus 1 is first mounted on the input unit 11. The input unit 11 includes, for example, two mounting tables 15 on which the carrier C is mounted. The carrier C is formed with a plurality of grooves (not illustrated) extending in the horizontal direction to accommodate the surfaces of the substrate W in a state of being separated from each other. One substrate W is inserted into each of the grooves. Examples of the carrier C include a sealed front opening unify pod (FOUP). In the present invention, an open type container may be employed as the carrier C.

The dispensing unit 13 dispenses the carrier C storing the processed substrate W carried out from the substrate processing apparatus 1. Similarly to the input unit 11, the dispensing unit 13 functioning in this manner includes, for example, two mounting tables 17 for mounting the carrier C. The input unit 11 and the dispensing unit 13 are also referred to as load ports.

### <3. Stocker Block>

The stocker block 5 is disposed adjacent to the rear of the carry-in/out block 3. The stocker block 5 includes a transfer storage unit ACB that stocks and manages the carrier C. The transfer storage unit ACB includes a transfer mechanism 19 that transfers the carrier C and a shelf 21 on which the carrier C is mounted. The number of carriers C that can be stocked by the stocker block 5 is one or more.

The stocker block 5 has a plurality of shelves 21 on which the carrier C is mounted. The shelf 21 is provided on a partition wall separating the stocker block 5 and the transfer block 7. The shelf 21 includes a stock shelf 21b on which the carrier C is simply temporarily mounted, and a carrier mounting shelf 21a for taking out and storing a substrate on which a first transfer mechanism HTR included in the transfer block 7 accesses. The carrier mounting shelf 21a for taking out and storing a substrate corresponds to a carrier mounting shelf for taking out and storing a substrate of the present invention. The carrier mounting shelf 21a has a configuration in which the carrier C is mounted for taking in and out the substrate W from the carrier C. In the present embodiment, one carrier mounting shelf 21a for taking out and storing a substrate is provided, but a plurality of carrier mounting shelves 21a for taking out and storing substrates may be provided. The transfer mechanism 19 takes in the carrier C storing the unprocessed substrate W from the input unit 11 and mounts the carrier C on the carrier mounting shelf 21a for taking out and storing a substrate. At this time, the transfer mechanism 19 can also temporarily mount the carrier C on the stock shelf 21b before mounting the carrier C on the carrier mounting shelf 21a. Further, the transfer storage unit ACB receives the carrier C storing the processed substrate W from the carrier mounting shelf 21a and mounts the carrier C on the dispensing unit 13. At this time, the transfer mechanism 19 can also temporarily mount the carrier C on the stock shelf 21b before mounting the carrier C on the dispensing unit 13. The number of carrier mounting shelves 21a included in the stocker block 5 is one or more.

### <4. Transfer Block>

The transfer block 7 is disposed behind and adjacent to the stocker block 5. The transfer block 7 includes a first transfer mechanism HTR that can access the carrier C mounted on the carrier mounting shelf 21a for taking out and storing a substrate, an HVC attitude changing unit 20 that collectively changes the attitude of the plurality of substrates W from the horizontal attitude to the vertical attitude, and a pusher mechanism 22. The first transfer mechanism HTR corresponds to the substrate handling mechanism of the present invention, and the HVC attitude changing unit 20 corresponds to a first attitude changing mechanism of the present invention. Further, in the transfer block 7, a substrate handover position P for handing over and receiving the plurality of substrates W to and from a second transfer mechanism WTR provided in a batch substrate transfer region R4 is set. The first transfer mechanism HTR, the HVC attitude changing unit 20, and the pusher mechanism 22 are arranged in this order in the Y direction.

The first transfer mechanism HTR is provided on the right of the rear of the transfer storage unit ACB of the stocker block 5. The first transfer mechanism HTR is a mechanism for collectively taking out a plurality of substrates W from the carrier C mounted on the carrier mounting shelf 21a for taking out and storing a substrate or collectively storing a plurality of processed substrates W in the carrier C. The first transfer mechanism HTR includes a plurality of (for example, 25) hands 71 that collectively transfer the plurality of substrates W. One hand 71 supports one substrate W. Therefore, the first transfer mechanism HTR can transfer only one substrate W. The first transfer mechanism HTR collectively takes out a plurality of (for example, 25) substrates W from the carrier C mounted on the carrier mounting shelf 21a of the stocker block 5. Then, the first transfer mechanism HTR can transfer the plurality of gripped substrates W to a support table 20A of the HVC attitude changing unit 20. The HVC attitude changing unit 20 changes the plurality of received substrates W in the horizontal attitude to the vertical attitude. The pusher mechanism 22 is configured to hold and move the plurality of substrates W in the vertical attitude up, down, left, and right.

Further, the first transfer mechanism HTR collectively receives a plurality of processed substrates W from the processing block 9 to be described later. Then, the first transfer mechanism HTR stores the processed substrates W in the empty carrier C mounted on the carrier mounting shelf 21a for taking out and storing a substrate included in the stocker block 5. The plurality of substrates W waiting at the exit of the processing block 9 is in the horizontal attitude. Therefore, the first transfer mechanism HTR transfers the plurality of substrates W from the processing block 9 to the stocker block 5 while maintaining the horizontal attitude of the substrates W. As described above, the first transfer mechanism HTR is also configured to collectively transfer unprocessed substrates W from the carrier C to the transfer block 7, and is also configured to collectively transfer the processed substrates W from the processing block 9 to the carrier C.

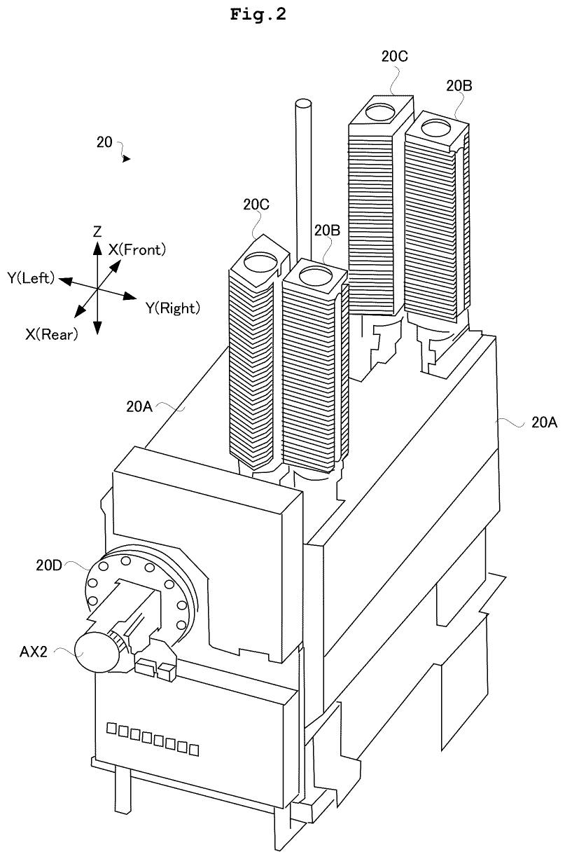

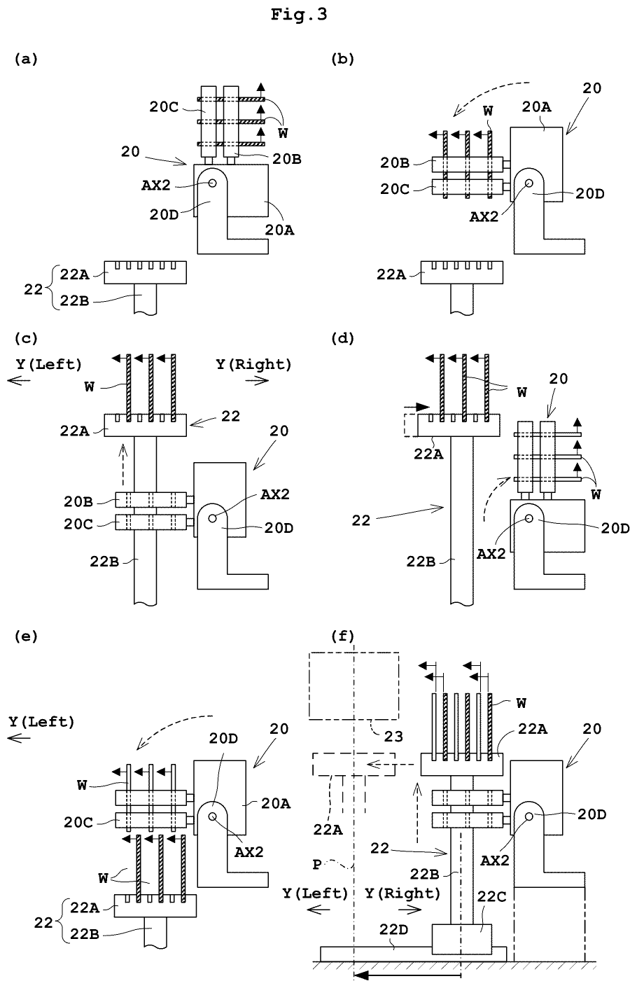

FIG. 2 illustrates the HVC attitude changing unit 20 of a first embodiment. The HVC attitude changing unit 20 includes a pair of horizontal holding units 20B and a pair of vertical holding units 20C extending in the vertical direction (Z direction). The support table 20A has a support surface extending in an XY plane that supports the horizontal holding unit 20B and the vertical holding unit 20C. The rotation drive mechanism 20D is configured to rotate the horizontal holding unit 20B and the vertical holding unit 20C by 90° together with the support table 20A. With this rotation, the horizontal holding unit 20B and the vertical holding unit 20C are configured to extend in the left-right direction (Y direction). Note that FIG. 3 is a schematic view describing the operation of the HVC attitude changing unit 20. Hereinafter, the configuration of each unit will be described with reference to FIGS. 2 and 3.

The horizontal holding unit 20B supports the plurality of substrates W in the horizontal attitude from below. That is, the horizontal holding unit 20B has a comb-shaped structure having a plurality of protrusions corresponding to the substrate W to be supported. Between adjacent protrusions, there is an elongated recess in which a peripheral edge portion of the substrate W is located. When the peripheral edge portion of the substrate W is inserted into the recess, the lower surface of the substrate W in the horizontal attitude comes into contact with an upper surface of the protrusion, and the substrate W is supported in the horizontal attitude.

The vertical holding unit 20C supports the plurality of substrates W in the vertical attitude from below. That is, the vertical holding unit 20C has a comb-shaped structure having a plurality of protrusions corresponding to the substrates W to be supported. There is an elongated V-shaped groove in which the peripheral edge portion of the substrate W is located between adjacent protrusions. When the peripheral edge portion of the substrate W is inserted into the V groove, the substrate W is clamped by the V groove and supported in a vertical attitude. Since the two vertical holding units 20C are provided on the support table 20A, the substrate W is clamped by different V-grooves at two positions of the peripheral edge portion.

The pair of horizontal holding units 20B and the pair of vertical holding units 20C extending in the vertical direction (Z direction) are provided along a virtual circle corresponding to the substrate W in a horizontal attitude so as to surround the substrate W to be held. The pair of horizontal holding units 20B is separated by the diameter of the substrate W, and holds one end of the substrate W and the other end that is the farthest from the one end. In this manner, the pair of horizontal holding units 20B supports the substrate W in the horizontal attitude. On the other hand, the pair of vertical holding units 20C is separated by a distance shorter than the diameter of the substrate W, and supports a predetermined portion of the substrate W and a specific portion located in the vicinity of the predetermined portion. In this manner, the pair of vertical holding units 20C supports the substrate W in the vertical attitude. The pair of horizontal holding units 20B is at the same position in the left-right direction (Y direction), and the pair of vertical holding units 20B is at the same position in the left-right direction (Y direction). The pair of vertical holding units 20B is provided on the side in the direction (leftward direction) in which the support table 20A is rotated and tilted relative to the pair of horizontal holding units 20B.

The rotation drive mechanism 20D rotatably supports the support table 20A by at least 90° around a horizontal axis AX2 extending in the front-rear direction (X direction). When the support table 20A in the horizontal state is rotated by 90°, the support table 20A becomes the vertical state, and the attitude of the plurality of substrates W held by the vertical holding units 20B and 20C is changed from the horizontal attitude to the vertical attitude.

As illustrated in FIG. 3(f), the pusher mechanism 22 includes a pusher 22A on which the substrates W in the vertical attitude can be mounted, an elevation rotation unit 22B that rotates and raises/lowers the pusher 22A, a horizontal movement unit 22C that moves the pusher 22A in the left-right direction (Y direction), and a rail 22D that guides the horizontal movement unit 22C and extends in the left-right direction (Y direction). The pusher 22A is configured to support a lower portion of each of a plurality of (for example, 50) substrates W in the vertical attitude. The elevation rotation unit 22B is provided below the pusher 22A, and includes an extendable mechanism that raises and lowers the pusher 22A in the vertical direction. In addition, the elevation rotation unit 22B can rotate the pusher 22A at least 180° around the vertical axis. The horizontal movement unit 22C is configured to support the elevation rotation unit 22B, and horizontally moves the pusher 22A and the elevation rotation unit 22B. The horizontal movement unit 22C can move the pusher 22A from the pick-up position close to the HVC attitude changing unit 20 to the substrate handover position P by being guided by the rail 22D. Further, the horizontal movement unit 22C can also shift the substrates W in the vertical attitude by a distance corresponding to a half pitch in the substrate arrangement of the pusher 22A in the arrangement direction of the substrates W.

Here, operations of the HVC attitude changing unit 20 and the pusher mechanism 22 will be described. The HVC attitude changing unit 20 and the pusher mechanism 22 arrange, for example, a total of 50 substrates W accommodated in two carriers C at a predetermined interval (for example, 5 mm) in a face-to-back manner. The 25 substrates W in the first carrier C are described as first substrates W1 belonging to a first substrate group. Similarly, the 25 substrates W in the second carrier C are described as second substrates W2 belonging to a second substrate group. Note that, in FIGS. 3A to 3F, for convenience of drawing, the number of first substrates W1 is three, and the number of second substrates W2 is three.

FIG. 3(a) illustrates a state in which the first substrates W1 in the horizontal attitude are collectively transferred to the HVC attitude changing unit 20 by the first transfer mechanism HTR. At this time, device surfaces (surfaces on which a circuit pattern is formed) of the first substrates W1 face upward. The 25 first substrates W1 are arranged at a predetermined interval (for example, 10 mm). The interval of 10 mm is called full pitch (normal pitch). The first substrates W1 in this state are held by the horizontal holding unit 20B. Note that the pusher 22A at this time is at a pick-up position below the support table 20A.

FIG. 3(b) illustrates a state when the support table 20A of the HVC attitude changing unit 20 is rotated by 90° by the rotation drive mechanism 20D. As described above, in the HVC attitude changing unit 20, the attitude of the 25 first substrates W1 is changed from the horizontal attitude to the vertical attitude. The first substrates W1 in this state are held by the vertical holding unit 20C.

FIG. 3(c) illustrates a state in which the pusher 22A is moved upward from the pick-up position to a position immediately above the pick-up position. This upward movement is performed by the elevation rotation unit 22B. As described above, when the pusher 22A moves from the lower side to the upper side of the first substrates W1, the first substrates W1 supported by the vertical holding unit 20C of the HVC attitude changing unit 20 are pulled out from the vertical holding unit 20C and are moved onto the pusher 22A. Grooves in which the substrates W are clamped are provided on the upper surface of the pusher 22A. The first substrates W1 are supported by these grooves arranged at equal intervals. Since the grooves are arranged at a half pitch and the first substrates W1 are arranged at a full pitch in the HVC attitude changing unit 20, the grooves in which the first substrates W1 are clamped and the empty grooves that do not support the substrates W are alternately arranged on the upper surface of the pusher 22A located immediately above.

FIG. 3(d) illustrates an operation in which the pusher 22A moves by a half pitch width and an operation in which the support table 20A of the HVC attitude changing unit 20 is reversely rotated by 90° by the rotation drive mechanism 20D. The HVC attitude changing unit 20 in this state can support the second substrates W2. FIG. 3(d) illustrates a state when the second substrates W2 have already been transferred to the HVC attitude changing unit 20. Note that, in FIG. 3(d), the second substrates W2 are supported by the horizontal holding unit 20B.

When the pusher 22A at the position immediately above in the state of FIG. 3(d) returns to the original pick-up position, the HVC attitude changing unit 20 can rotate the support table 20A again by 90°.

FIG. 3(e) illustrates a state when the support table 20A is actually rotated again. At this time, since the pusher 22A is moved by the half pitch width, when the pusher 22A is moved again to the position immediately above as illustrated in FIG. 3(f), the second substrates W2 do not interfere with the first substrates W1 and fit into the empty grooves interposed between the first substrates W1 on the upper surface of the pusher 22A. In this manner, a lot in which the first substrates W1 and the second substrates W2 are alternately arranged is formed. Note that, in FIG. 3(e), the second substrates W2 are supported by the vertical holding unit 20C. Since the lot is configured by arranging the substrates W in a face-to-back manner, the device surfaces of the substrates W constituting the lot all face the left side in FIG. 3(f).

FIG. 3(f) illustrates a state when the pusher 22A moves to the position immediately above again. Then, the lot generated in the pusher 22A is transferred in the left direction (Y direction) by the horizontal movement unit 22C and moved to the substrate handover position P.

Note that, in the following description, the configuration of the substrate arrangement to be processed is not questioned. That is, the main part of the present invention has a configuration similar to that of both a normal lot (for example, 25 substrates W arranged at full pitch) and the above-described batch lot. In the following description, the processing target is simply referred to as a lot or a plurality of substrates W.

### <5. Processing Block>

The processing block 9 performs various types of processing on the plurality of substrates W. The processing block 9 is divided into a batch processing region R1, a single wafer processing region R2, a single substrate transfer region R3, and a batch substrate transfer region R4 arranged in the width direction (Y direction). Each region extends in the front-rear direction (X direction). Specifically, the batch processing region R1 is arranged on the left side in the processing block 9. The single wafer processing region R2 is arranged on the right side in the processing block 9. The single substrate transfer region R3 is disposed at a position interposed between the batch processing region R1 and the single wafer processing region R2, that is, at a central portion in the processing block 9. The batch substrate transfer region R4 is disposed on the leftmost side of the processing block 9.

### <5.1. Batch Processing Region>

The batch processing region R1 in the processing block 9 is a rectangular region extending in the front-rear direction (X direction). One end side (front side) of the batch processing region R1 is adjacent to the transfer block 7. The other end side of the batch processing region R1 extends in a direction away from the transfer block 7 (backward side).

The batch processing region R1 includes a batch type processing unit that mainly performs batch type processing. Specifically, in the batch processing region R1, a plurality of batch processing units BPU1 to BPU3 for collectively submerging a plurality of substrates W in a direction in which the batch processing region R1 extends is arranged. The arrangement of the batch processing units BPU1 to BPU3 will be specifically described. The first batch processing unit BPU1 is adjacent to the transfer block 7 from the rear. The second batch processing unit BPU2 is adjacent to the first batch processing unit BPU1 from the rear. The third batch processing unit BPU3 is adjacent to the second batch processing unit BPU2 from the rear. Therefore, the first batch processing unit BPU1, the second batch processing unit BPU2, and the third batch processing unit BPU3 are sequentially separated from the transfer block 7. Then, an underwater attitude changing unit 25 that collectively changes the attitude of the plurality of substrates W between the vertical attitude and the horizontal attitude is provided at a position farthest from the transfer block 7 than the batch processing units BPU1 to BPU3. The underwater attitude changing unit 25 is adjacent to the third batch processing unit BPU3 from the rear. Therefore, the underwater attitude changing unit 25 is provided at a position farthest from the transfer block 7 in the batch processing region R1. In this manner, the first batch processing unit BPU1, the second batch processing unit BPU2, the third batch processing unit BPU3, and the underwater attitude changing unit 25 are arranged in this order in the extending direction of the batch processing region R1 (front-rear direction: X direction).

Specifically, the first batch processing unit BPU1 includes a batch chemical solution treatment tank CHB1 that collectively performs chemical solution treatment on the lot, and a lifter LF1 that raises and lowers the lot. The batch chemical solution treatment tank CHB1 performs acid treatment on the lot. The acid treatment may be a phosphoric acid treatment, but may be a treatment using another acid. In the phosphoric acid treatment, etching treatment is performed on a plurality of substrates W constituting a lot. In the etching treatment, for example, nitride films on the surfaces of the substrates W are chemically etched.

The batch chemical solution treatment tank CHB1 stores a chemical solution such as a phosphoric acid solution. The batch chemical solution treatment tank CHB1 is provided with a lifter LF1 that moves the lot up and down. The batch chemical solution treatment tank CHB1 supplies, for example, a chemical solution from below upward to convect the chemical solution. The lifter LF1 moves up and down in the vertical direction (Z direction). Specifically, the lifter LF1 moves up and down between a treatment position corresponding to the inside of the batch chemical solution treatment tank CHB1 and a handover position corresponding to the upper side of the batch chemical solution treatment tank CHB1. The lifter LF1 holds the lot including the substrates W in the vertical attitude. The lifter LF1 hands over and receives the lot to and from the second transfer mechanism WTR at the handover position. When the lifter LF1 descends from the handover position to the processing position while holding the lot, the entire regions of the substrates W are located below the liquid surface of the chemical solution. When the lifter LF1 rises from the processing position to the handover position while holding the lot, the entire regions of the substrates W are located above the liquid surface of the chemical solution.

Specifically, the second batch processing unit BPU2 includes a batch chemical solution treatment tank CHB2 and a lifter LF2 that raises and lowers the lot. The batch chemical solution treatment tank CHB2 has a configuration similar to that of the batch chemical solution treatment tank CHB1 described above. That is, the batch chemical solution treatment tank CHB2 stores the chemical solution described above, and is provided with the lifter LF2. The batch chemical solution treatment tank CHB2 performs a treatment similar to that of the batch chemical solution treatment tank CHB1 on the lot. The substrate processing apparatus 1 of this example includes a plurality of treatment tanks capable of performing the same chemical solution treatment. This is because the phosphoric acid treatment takes more time than other treatments. The phosphoric acid treatment requires a long time (for example, 60 minutes). Accordingly, in the apparatus of the present example, the acid treatment can be performed in parallel by a plurality of batch chemical solution treatment tanks. Therefore, the lot is acid-treated in either the batch chemical solution treatment tank CHB1 or the batch chemical solution treatment tank CHB2. With this configuration, the throughput of the apparatus is increased.

Specifically, the third batch processing unit BPU3 includes a batch rinse treatment tank ONB that stores a rinse liquid, and a lifter LF3 that raises and lowers the lot. The batch rinse treatment tank ONB has a configuration similar to that of the batch chemical solution treatment tank CHB1 described above. That is, the batch rinse treatment tank ONB accommodates the rinse solution and is provided with the lifter LF3. Unlike other treatment tanks, the batch rinse treatment tank ONB stores pure water, and is provided for the purpose of washing off the chemical solution adhering to the plurality of substrates W. In the batch rinse treatment tank ONB, when the specific resistance of the pure water in the tank increases to a predetermined value, the cleaning treatment ends.

As described above, the batch chemical solution treatment tank CHB1 and the batch chemical solution treatment tank CHB2 in the first embodiment are located closer to the transfer block 7 than the batch rinse treatment tank ONB.

The underwater attitude changing unit 25 includes an immersion tank 43 that immerses the lot in a liquid, a lifter LF4 that raises and lowers the lot, and an attitude changing mechanism 45 that changes the attitude of the lot. The immersion tank 43 stores pure water and prevents drying of the substrates W in the tank. The lifter LF4 that has received the lot from the second transfer mechanism WTR at the handover position above the immersion tank 43 lowers the substrates W to an immersion position (corresponding to the treatment position in the batch chemical solution treatment tank CHB1) and immerses the entire regions of the substrates W in the pure water. The attitude changing mechanism 45 changes the attitude of the substrates W constituting the lot from the vertical attitude to the horizontal attitude by rotating the lot immersed in the pure water by 90 degrees. The lifter LF4 can raise and lower the lot including the substrates W in the vertical attitude and can raise and lower the lot including the substrates W in the horizontal attitude. The lifter LF4 can bring the substrates W in the horizontal attitude one by one from the liquid to above the liquid surface by raising the lot stepwise in units of arrangement pitch of the substrates W. The underwater attitude changing unit 25 corresponds to a second attitude changing mechanism of the present invention.

A center robot CR described later can transfer the substrates W supported by the lifter LF4 one by one. The lifter LF4 at this time can rise, for example, by a width of five substrates when the center robot CR approaches for substrate transfer. In this case, the five substrates W are collectively exposed from the liquid surface to the air. By the lifter LF4 moving by a stroke longer than the arrangement pitch of the substrates W, a distance in the vertical direction (Z direction) from the liquid surface of the immersion tank 43 to the center robot CR can be sufficiently secured. Thus, a distal end of a hand 29 of the center robot CR is not immersed in the liquid stored in the immersion tank 43. After the center robot CR that has acquired the substrate W moves away from the lifter LF4, the lifter LF4 descends for the purpose of preventing the four substrates W brought into the air from being dried as the lifter LF4 rises. At this time, the lifter LF4 does not need to descend by a stroke corresponding to the five substrates W, and only needs to descend by a stroke corresponding to the four substrates W. This is because the uppermost substrate W among the five substrates W brought to above the liquid surface is transferred to the center robot CR and is not on the lifter LF4. With such a configuration, the moving time of the lifter LF4 can be shortened, and an apparatus with a high throughput can be provided. Note that when the number of substrates W remaining in the lifter LF4 is less than five, the moving distance of the lifter LF4 can be shortened according to the insufficient number of substrates W.

### <5.2. Single Wafer Processing Region>

The single wafer processing region R2 in the processing block 9 is a rectangular region extending in the front-rear direction (X direction). One end side (front side) of the single wafer processing region R2 is adjacent to the transfer block 7. The other end side of the batch processing region R1 extends in a direction away from the transfer block 7 (backward side).

The single wafer processing region R2 in the processing block 9 mainly includes chambers related to liquid treatment and chambers related to drying treatment. Specifically, the single wafer processing region R2 includes a single wafer liquid treatment chamber SWP1 and a single wafer liquid treatment chamber SWP2 for liquid treatment of the substrates W one by one, a single wafer drying treatment chamber SWP3 for drying the substrates W subjected to liquid treatment one by one, and a buffer unit 31 for mounting a plurality of substrates W in a horizontal attitude at the same pitch as that of the carrier C in the vertical direction. The single wafer liquid treatment chamber SWP1 is disposed on the farthest side in the front-rear direction (X direction) in the single wafer processing region R2. In other words, the single wafer liquid treatment chamber SWP1 faces the underwater attitude changing unit 25 in the width direction (Y direction) with the single substrate transfer region R3 interposed therebetween. The single wafer liquid treatment chamber SWP2 is adjacent to the front of the single wafer liquid treatment chamber SWP1. The single wafer drying treatment chamber SWP3 is adjacent to the front of the single wafer liquid treatment chamber SWP2. The buffer unit 31 is adjacent to the front side of the single wafer drying treatment chamber SWP3. Therefore, the buffer unit 31 is provided at a position closest to the transfer block 7 in the single wafer processing region R2. In this manner, the buffer unit 31, the single wafer drying treatment chamber SWP3, the single wafer liquid treatment chamber SWP2, and the single wafer liquid treatment chamber SWP1 are arranged in this order in the extending direction of the single wafer processing region R2 (front-rear direction: X direction). The buffer unit 31 corresponds to a substrate mounting unit of the present invention.

Each of the single wafer liquid treatment chamber SWP1 and the single wafer liquid treatment chamber SWP2 includes a rotation processing unit 33 that rotates the substrate W in the horizontal attitude and a nozzle 35 that supplies a treatment liquid toward the substrate W. The rotation processing unit 33 rotationally drives the substrate W in an XY plane (horizontal plane). The nozzle 35 is swingable between a standby position away from the rotation processing unit 33 and a supply position located above the rotation processing unit 33. The treatment liquid may be isopropyl alcohol (IPA), pure water, or a mixed liquid thereof. Each of the single wafer liquid treatment chamber SWP1 and the single wafer liquid treatment chamber SWP2 is configured to perform, for example, a cleaning treatment on the substrate W with pure water and then perform a preliminary drying treatment with IPA.

The single wafer drying treatment chamber SWP3 is, for example, a supercritical fluid chamber. The supercritical fluid chamber performs a drying treatment of the substrate W with, for example, carbon dioxide that has become the supercritical fluid. As the supercritical fluid, a fluid other than carbon dioxide may be used for drying. The supercritical state is obtained by placing carbon dioxide under inherent critical pressure and temperature. The specific pressure is 7.38 MPa and the temperature is 31° C. In the supercritical state, the surface tension of the fluid becomes zero, so that the gas-liquid interface does not affect the circuit pattern on the surface of the substrate W. Therefore, when the drying treatment of the substrate W is performed with the supercritical fluid, it is possible to prevent occurrence of what is called a pattern collapse in which the circuit pattern is collapsed on the substrate W.

As described above, the single wafer drying treatment chamber SWP3 in the first embodiment is located closer to the transfer block 7 than the single wafer liquid treatment chambers SWP1 and SWP2.

The buffer unit 31 has a plurality of mounting shelves 39 arranged in the vertical direction (Z direction), and can store at least one lot (for example, 25 pieces) of substrates W. The mounting shelves 39 are arranged at the full pitch described above. The buffer unit 31 is used when a lot is handed over between the processing block 9 and the transfer block 7. This point will be described below. When the lot is dispensed from the processing block 9 to the transfer block 7, first, the center robot CR described later in the processing block 9 mounts the substrates W subjected to the drying treatment one by one on the buffer unit 31. In this manner, the substrates W for one lot are stored in the buffer unit 31 at a full pitch. Then, the lot stored in the buffer unit 31 is collectively gripped by the first transfer mechanism HTR in the transfer block 7. That is, the center robot CR in the processing block 9 can access the buffer unit 31 from the width direction (Y direction), and the first transfer mechanism HTR in the transfer block 7 can access the buffer unit 31 from the front-rear direction (X direction). Note that the center robot CR can move up and down in the vertical direction (Z direction) so that the substrates W can be handed over between the plurality of mounting shelves 39.

### <5.3. Single Substrate Transfer Region>

The single substrate transfer region R3 in the processing block 9 is a rectangular region extending in the front-rear direction (X direction). The single substrate transfer region R3 is interposed between the batch processing region R1 and the single wafer processing region R2, and has one end adjacent to the transfer block 7 and the other end extending in a direction away from the transfer block 7.

The single substrate transfer region R3 includes the center robot CR that transfers the substrate W in a horizontal attitude. The center robot CR transfers the substrate W between the underwater attitude changing unit 25, the single wafer liquid treatment chambers SWP1 to SWP3, and the buffer unit 31. The center robot CR corresponds to a single substrate transfer mechanism of the present invention. The center robot CR includes a hand 29 capable of holding one substrate W in a horizontal attitude. The center robot CR may be configured to include another hand 29 superimposed in the vertical direction (Z direction). The center robot CR can reciprocate in the front-rear direction (X direction). The center robot CR can reciprocate in the vertical direction (Z direction). The center robot CR can turn in the XY plane (horizontal plane). Therefore, the hand 29 of the center robot CR can face the batch processing region R1 side related to the batch type processing or face the single wafer processing region R2 side related to the single wafer processing by rotating around a rotation axis extending in the Z direction. The center robot CR corresponds to the single substrate transfer mechanism of the present invention.

The hand 29 of the center robot CR is movable forward and backward in the XY plane (horizontal plane). Therefore, the hand 29 can receive the substrate W in the horizontal attitude from the underwater attitude changing unit 25 in the batch processing region R1, or can hands over and receive the substrate W in the horizontal attitude to and from each of the single wafer liquid treatment chambers SWP1 to SWP3 in the single wafer processing region R2. Note that when the center robot CR includes two hands 29, the center robot CR receives two substrates W from the underwater attitude changing unit 25, and hands over the substrates W to the single wafer liquid treatment chamber SWP1 or the single wafer liquid treatment chamber SWP2 which is different one by one with respect to the single wafer processing region R2.

### <5.4. Batch Substrate Transfer Region>

The batch substrate transfer region R4 in the processing block 9 is a rectangular region extending in the front-rear direction (X direction). The batch substrate transfer region R4 is provided along the outer edge of the batch processing region R1, and has one end side extending to the transfer block 7 and the other end side extending in a direction away from the transfer block 7.

The batch substrate transfer region R4 is provided with the second transfer mechanism WTR that collectively transfers a plurality of substrates W. The second transfer mechanism WTR collectively transfers a plurality of substrates W (specifically, a lot) among the substrate handover position P defined in the transfer block 7, each of the batch processing units BPU1 to BPU3, and the underwater attitude changing unit 25. The second transfer mechanism WTR is configured to be able to reciprocate in the front-rear direction (X direction) across the transfer block 7 and the processing block 9. The second transfer mechanism WTR is movable not only to the batch substrate transfer region R4 in the processing block 9 but also to the substrate handover position P in the transfer block 7. The second transfer mechanism WTR corresponds to a batch substrate transfer mechanism of the present invention.

The second transfer mechanism WTR includes a pair of hands 23 that transfers a lot. The pair of hands 23 includes, for example, a rotation shaft oriented in the width direction (Y direction), and swings around the rotation shaft. The pair of hands 23 holds both ends of the plurality of substrates W constituting the lot. The second transfer mechanism WTR hands over and receive the lot to and from the substrate handover position P in the transfer block 7, the respective lifters LF1 to LF3 belonging to the batch processing units BPU1 to BPU3, and the lifter LF4 belonging to the underwater attitude changing unit 25.

As described above, in the substrate processing apparatus 1 of the present example, the elongated batch substrate transfer region R4, the batch processing region R1, the single substrate transfer region R3, and the single wafer processing region R2 extending in the front-rear direction (X direction) are arranged in this order from the left side to the right side.

### <5.5. Window>

As described above, the buffer unit 31 in the processing block 9 is adjacent to the transfer block 7. The first transfer mechanism HTR provided in the transfer block 7 can access the buffer unit 31. Therefore, the first transfer mechanism HTR can collectively hands over the plurality of substrates W mounted on the buffer unit 31 in a state of being arranged in the vertical direction at the same pitch as that of the carrier C in the horizontal attitude. A window 77 is provided in a partition wall separating the transfer block 7 and the processing block 9. Thus, the first transfer mechanism HTR of the transfer block 7 can access the buffer unit 31 of the processing block 9.

The substrate processing apparatus 1 of this example includes, in addition to the above-described units, a central processing unit (CPU) 75 that controls each mechanism and each processing unit, and a storage unit 76 that stores various types of information necessary for a processing process such as programs and setting values. Note that the specific configuration of the CPU is not particularly limited. One CPU may be provided in the entire apparatus, or one or more CPUs may be provided in each block. The same applies to the storage unit 76. The control performed by the CPU is, for example, control related to operations of the first transfer mechanism HTR, the second transfer mechanism WTR, the HVC attitude changing unit 20, the pusher mechanism 22, the center robot CR, and the like.

### <Flow of Substrate Processing>

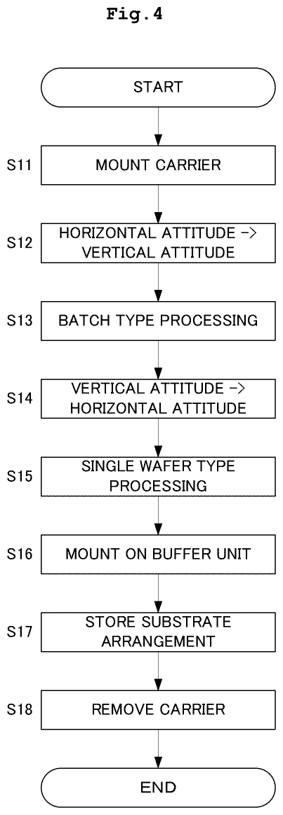

FIG. 4 is a flowchart describing the flow of the substrate processing of this example. In the substrate processing of this example, for example, each processing related to etching of the surface of the substrate W in a semiconductor device manufacturing process is performed. Hereinafter, the flow of the substrate processing will be specifically described along the flowchart.

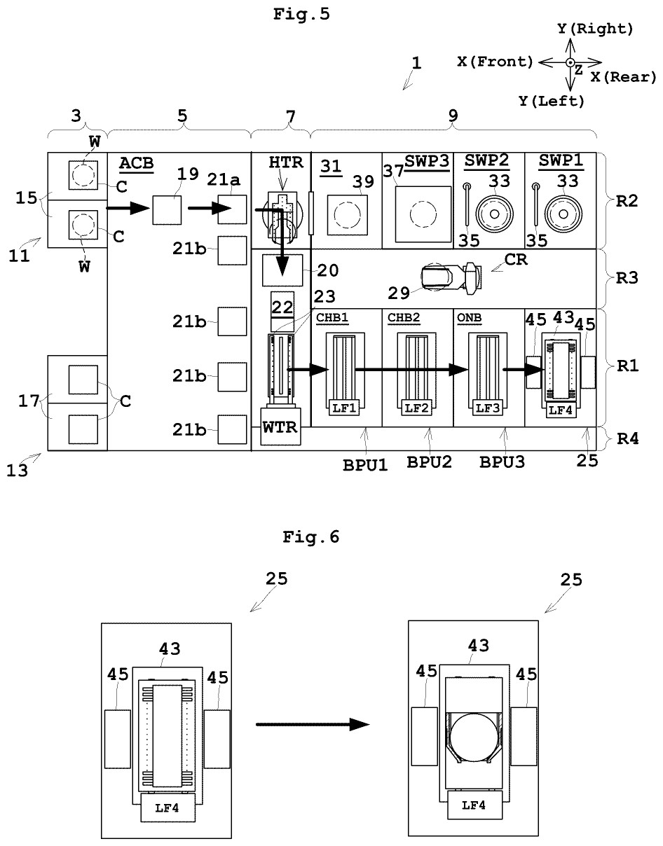

Step S11: The carrier C storing unprocessed substrates W is set on the mounting table 15 of the input unit 11. Thereafter, the carrier C is taken into the apparatus from the input unit 11, and is mounted on the carrier mounting shelf 21a for handover provided in the stocker block 5 by the transfer mechanism 19 (see FIG. 5).

Step S12: The first transfer mechanism HTR provided in the transfer block 7 collectively takes out the plurality of substrates W from the carrier C of the carrier mounting shelf 21a. Then, the first transfer mechanism HTR transfers the plurality of substrates W in the horizontal attitude to the HVC attitude changing unit 20. The HVC attitude changing unit 20 changes the attitude of the plurality of substrates W from the horizontal attitude to the vertical attitude and transfers the plurality of substrates W to the pusher mechanism 22. The pusher mechanism 22 transfers the substrates W in the vertical attitude to the substrate handover position P in a state of being arranged in the width direction (Y direction) (see FIG. 5).

Step S13: Batch type processing is performed. Specifically, the lot waiting at the substrate handover position P is collectively lifted in the vertical direction (Z direction) by the second transfer mechanism WTR, and then transferred in the front-rear direction (X direction). The plurality of substrates W in the vertical attitude is passed to the lifter LF1 of the first batch processing unit BPU1 or the lifter LF2 of the second batch processing unit BPU2 in a state of being arranged in the width direction (Y direction). The lifter LF1 and the lifter LF2 that receive the substrate W are at the handover position. In this manner, the lot is located above the liquid surface in either the batch chemical solution treatment tank CHB1 or the batch chemical solution treatment tank CHB2. FIG. 5 illustrates a state in which the lot is treated in the batch chemical solution treatment tank CHB1. The lifter LF1 that has received the lot descends and immerses the lot in the batch chemical solution treatment tank CHB1. In this manner, the chemical solution treatment for the lot is executed.

When the chemical solution treatment is completed, the lifter LF1 exposes the lot from the batch chemical solution treatment tank CHB1 above the liquid surface. The lot is then collectively lifted in the vertical direction (Z direction) by the second transfer mechanism WTR, and then transferred in the front-rear direction (X direction). The substrates W in the vertical attitude are passed to the lifter LF3 of the third batch processing unit BPU3 in a state of being arranged in the width direction (Y direction). The lifter LF3 at this time is at the handover position. In this manner, the lot is positioned above the liquid surface in the batch rinse treatment tank ONB. The lifter LF3 that has received the lot descends and immerses the lot in the batch rinse treatment tank ONB. In this manner, the cleaning treatment is performed on the lot (see FIG. 5).

When the cleaning treatment is completed, the lifter LF3 exposes the lot from the batch rinse treatment tank ONB above the liquid surface. The lot is then collectively lifted in the vertical direction (Z direction) by the second transfer mechanism WTR, and then transferred in the front-rear direction (X direction). The plurality of substrates W in the vertical attitude is passed to the underwater attitude changing unit 25 in a state of being arranged in the width direction (Y direction) (see FIG. 5). At this time, the lifter LF4 of the underwater attitude changing unit 25 waits in an attitude capable of holding the lot in the vertical attitude. Further, the lifter LF4 at this time is at the handover position.

As described above, in step 13, the second transfer mechanism WTR collectively receives the plurality of substrates W in the vertical attitude at the substrate handover position P of the transfer block 7, and transfers the received plurality of substrates W to the first batch processing unit BPU1 (alternatively, the second batch processing unit BPU2) related to the chemical solution treatment, the third batch processing unit BPU3 related to the rinse treatment, and the underwater attitude changing unit 25 in this order.

Step S14: Here, attitude changing that is a process after the batch type processing is executed. FIG. 6 illustrates a process related to attitude changing in the entire process of substrate processing. In the underwater attitude changing unit 25, the lifter LF4 at the handover position receives the lot, and the lifter LF4 is moved to the immersion position. Then, the lot is located below the liquid surface of the immersion tank 43. The attitude changing mechanism 45 changes the attitude of the plurality of substrates W from the vertical attitude to the horizontal attitude by rotating the lot by 90° in water. As the rotation direction at this time, a direction in which the surface of the substrate W on which the circuit pattern is formed faces upward is selected. As described above, the underwater attitude changing unit 25 changes the attitude of the received plurality of substrates W in the vertical attitude to the horizontal attitude.

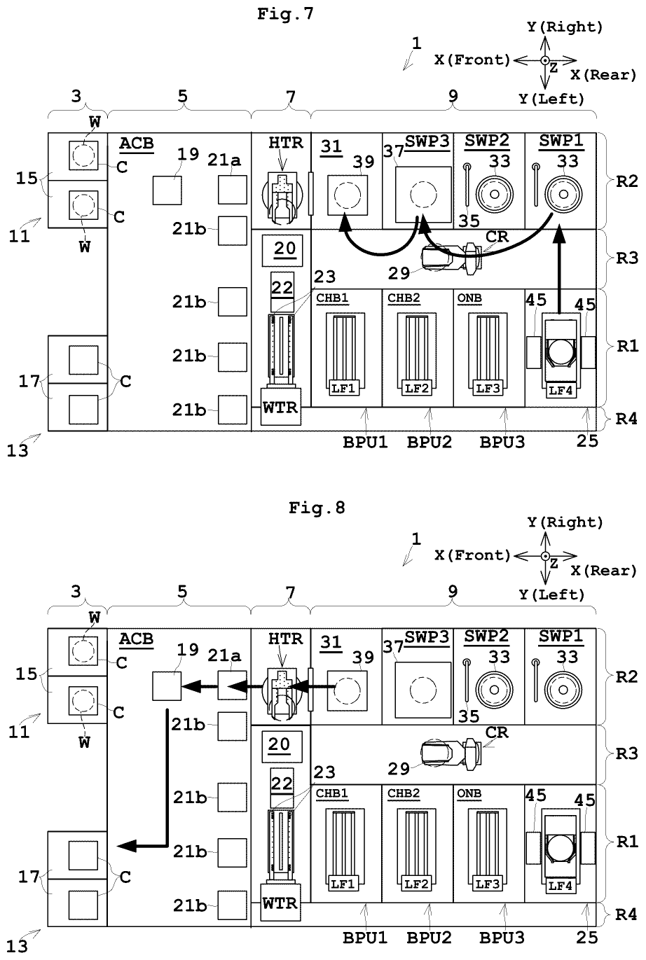

Step S15: Single wafer processing that is a process after the attitude changing processing is executed. FIG. 7 illustrates a process related to the single wafer processing among all the processes of the substrate processing. The substrates W in the horizontal attitude waiting in the underwater attitude changing unit 25 are lifted one by one in the vertical direction (Z direction) by the center robot CR, and then transferred to either the single wafer liquid treatment chamber SWP1 or the single wafer liquid treatment chamber SWP2. FIG. 7 illustrates a state in which the substrates W are mounted on the single wafer liquid treatment chamber SWP1. The substrate W preliminarily dried by the single wafer liquid treatment chamber SWP1 is lifted in the vertical direction (Z direction) by the center robot CR and then transferred to the single wafer drying treatment chamber SWP3. Then, the substrate W is stored in the supercritical fluid chamber 37 and subjected to the drying treatment.

Step S16: The substrate W after the single wafer processing is mounted on the buffer unit 31. Specifically, the substrate W subjected to the drying treatment is taken out from the supercritical fluid chamber 37 by the center robot CR and mounted on the buffer unit 31. When such substrate transfer is continued, the buffer unit 31 holds 25 substrates W arranged in the vertical direction (Z direction) at a full pitch in the horizontal attitude. In this manner, the buffer unit 31 holds the lot after the substrate processing (see FIG. 7). Note that, as described in step S15 and this step, the center robot CR transfers the substrates W changed to the horizontal attitude by the underwater attitude changing unit 25 one by one to the single wafer liquid treatment chamber SWP1, the single wafer drying treatment chamber SWP3, and the buffer unit 31 in this order.

Step S17: The plurality of substrates W mounted on the buffer unit 31 is stored in the carrier C. FIG. 8 illustrates a process related to lot transfer in the entire process of substrate processing. The lot held in the buffer unit 31 is collectively gripped by the first transfer mechanism HTR. Then, the lot is returned to the empty carrier C waiting on the carrier mounting shelf 21a in the stocker block 5. In the substrate processing of this example, since the carrier C and the lot inside the carrier C are associated with each other, the lot retrieved from the carrier C returns to the same carrier C after being subjected to various treatments. The carrier C storing the lot is moved to the dispensing unit 13 provided on the side wall of the carry-in/out block 3. That is, when the plurality of substrates W is mounted on the buffer unit 31 in the processing block 9, the first transfer mechanism HTR collectively takes out the plurality of substrates W from the buffer unit 31, and collectively stores the plurality of substrates W taken out in the carrier C.

Step S18: The transfer mechanism 19 transfers the carrier C to the mounting table 17, and the carrier C is removed from the mounting table 17. In this manner, the substrate processing by the substrate processing apparatus 1 according to the present example ends.

As described above, according to the present example, the buffer unit 31 to and from which both the first transfer mechanism HTR and the center robot CR can hand over and receive the substrate(s) W is provided in the single wafer processing region R2. Therefore, the first transfer mechanism HTR can collectively receive the substrates W from the single wafer processing region R2 via the buffer unit 31. Further, the center robot CR can hand over the substrates W treated in the single wafer liquid treatment chamber SWP1, the single wafer liquid treatment chamber SWP2, and the single wafer drying treatment chamber SWP3 one by one to the buffer unit 31. With this configuration, the first transfer mechanism HTR collectively takes the substrates W in and out of the carrier C. Therefore, a potential of the first transfer mechanism HTR is drawn out, and the substrate processing apparatus 1 having a high throughput can be provided. Further, according to the present invention, in the batch processing region R1 in the processing block 9, since the underwater attitude changing unit 25 is disposed at a position farther from the transfer block 7 than each batch processing tank that performs predetermined processing on the substrates W, the plurality of substrates W subjected to the batch processing is transferred in a direction away from the transfer block 7 when moving toward the underwater attitude changing unit 25. Then, the plurality of substrates W whose attitude has been changed by the underwater attitude changing unit 25 is transferred in a direction approaching the transfer block 7 when the single wafer processing is performed. As described above, with a configuration to perform the batch processing while the substrates W are transferred in the processing block 9 in the direction away from the transfer block 7, and then perform the single wafer processing while the substrates W are transferred so as to approach the transfer block 7, the reciprocation of the substrates W in the processing block 9 is performed only once, and thus it is possible to provide the substrate processing apparatus 1 in which the transfer distance of the substrates W is short and the throughput is high.

Further, the substrates W whose attitude has been changed to the horizontal attitude by the underwater attitude changing unit 25 are arranged at a position close to the single wafer liquid treatment chamber SWP1 and the single wafer liquid treatment chamber SWP2. The single wafer liquid treatment chamber SWP1 and the single wafer liquid treatment chamber SWP2 are located at positions farther from the single wafer drying treatment chamber SWP3 and farther from the transfer block 7. On the other hand, the underwater attitude changing unit 25 is at a position farthest from the transfer block 7. From these, the single wafer liquid treatment chamber SWP1 and the single wafer liquid treatment chamber SWP2 are located closer to the underwater attitude changing unit 25 than the single wafer drying treatment chamber SWP3. With this configuration, the distance when the substrates W are transferred one by one from the batch processing region R1 to the single wafer processing region R2 is shortened. Therefore, according to the configuration of the present example, the throughput is high, and unexpected drying of the substrates W is prevented. Further, the time until the substrates W are carried out from the underwater attitude changing unit 25 and are carried into the single wafer liquid treatment chamber SWP1 and the single wafer liquid treatment chamber SWP2 is shortened, and contamination of the substrates W occurring during the transfer can be prevented as much as possible.

### Second Embodiment

Subsequently, a substrate processing apparatus 2 according to a second embodiment will be described. The substrate processing apparatus 2 according to the present example is different from the apparatus of the first embodiment in that the single wafer processing is performed before the batch type processing. A specific flow of the substrate processing will be described later.

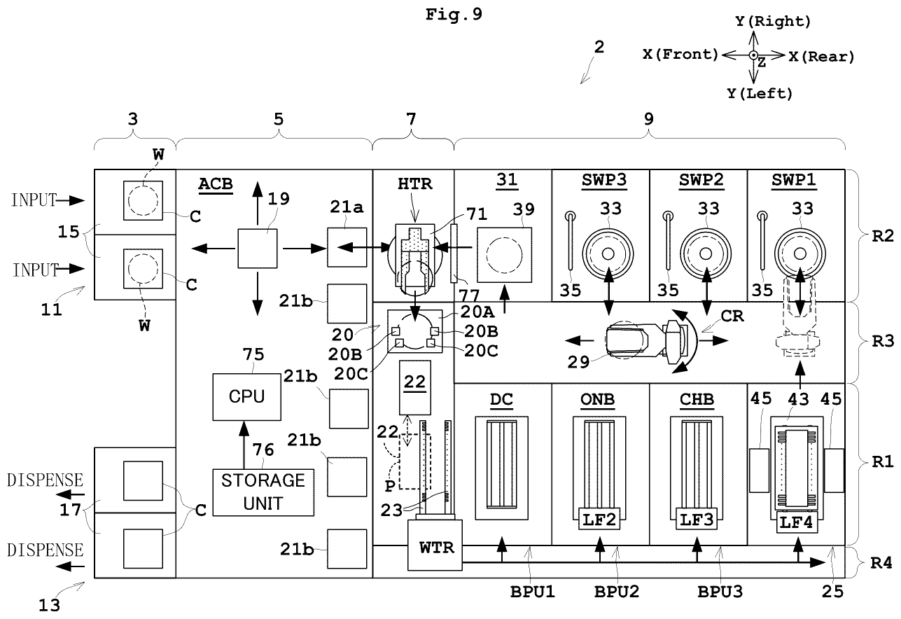

FIG. 9 illustrates an overall configuration of the substrate processing apparatus 2. The carry-in/out block 3, the stocker block 5, and the transfer block 7 in the substrate processing apparatus 2 are similar to those in the apparatus of the first embodiment. Further, the apparatus according to the present embodiment is also similar to the apparatus according to the first embodiment in that the center robot CR is provided in the single substrate transfer region R3 in the processing block 9 and the second transfer mechanism WTR is provided in the batch substrate transfer region R4. The apparatus of the present example is characterized by the batch processing region R1 and the single wafer processing region R2 in the processing block 9.

### <Batch Processing Region>

In the batch processing region R1 included in the processing block 9 of this example, the first batch processing unit BPU1, the second batch processing unit BPU2, the third batch processing unit BPU3, and the underwater attitude changing unit 25 are arranged in this order in a direction away from the transfer block 7 (front-rear direction: X direction). The first batch processing unit BP includes a batch drying chamber DC for collectively drying a plurality of substrates W constituting a lot, the second batch processing unit BPU2 includes the batch rinse treatment tank ONB and the lifter LF2 described above, and the third batch processing unit BPU3 includes the batch chemical solution treatment tank CHB and the lifter LF3 described above. The batch drying chamber DC is located closer to the transfer block 7 than the batch rinse treatment tank ONB. The batch rinse treatment tank ONB is on the side closer to the transfer block 7 than the batch chemical solution treatment tank CHB. As described above, the apparatus of the second embodiment is the same as the apparatus of the first embodiment in that the underwater attitude changing unit 25 is located farthest side with respect to the transfer block 7. However, in the apparatus of the second embodiment, unlike the apparatus of the first embodiment, the batch chemical solution treatment tank CHB is located on the side farther than the batch rinse treatment tank ONB with respect to the transfer block 7. A feature of the second embodiment is that the batch drying chamber DC related to drying of the substrates W is located on the nearer side than the batch rinse treatment tank ONB with respect to the transfer block 7.

The batch drying chamber DC has a drying chamber that accommodates the lot in which the substrates W in a vertical attitude are arranged. The drying chamber includes an inert gas supply nozzle that supplies an inert gas into the chamber and a vapor supply nozzle that supplies vapor of an organic solvent into the tank. The batch drying chamber DC first supplies an inert gas to the lot supported in the chamber to replace the atmosphere in the chamber with the inert gas. Then, decompression in the chamber is started. In a state where the inside of the chamber is decompressed, vapor of the organic solvent is supplied into the chamber. The organic solvent is discharged to the outside of the chamber together with moisture adhering to the substrates W. In this manner, the batch drying chamber DC performs drying of the lot. The inert gas at this time may be, for example, nitrogen, and the organic solvent may be, for example, IPA.

### <Single Wafer Processing Region>

In the single wafer processing region R2 included in the processing block 9 of this example, the buffer unit 31 and the single wafer liquid treatment chambers SWP1 to SWP3 for processing the substrates W one by one are arranged in this order in a direction away from the transfer block 7 (front-rear direction: X direction).

The single wafer liquid treatment chambers SWP1 to SWP3 can perform chemical solution treatment processing related to resist removal. That is, the nozzle 35 included in the single wafer processing unit can supply a liquid in which oxygen and ozone are dissolved in pure water. When the liquid is supplied to the surface of the substrate W rotated by the rotation processing unit 33, the resist formed on the surface is removed from the substrate W. Specifically, the resist may be a novolac-based positive resist. The single wafer liquid treatment chambers SWP1 to SWP3 can also supply pure water to the substrate W. When pure water is supplied to the substrate W, the resist remaining on the substrate W can flow out from the substrate W. Note that the single wafer liquid treatment chambers SWP1 to SWP3 are configured to perform pretreatment of batch type processing, and specific treatment contents are not particularly limited.

### <Flow of Substrate Processing>

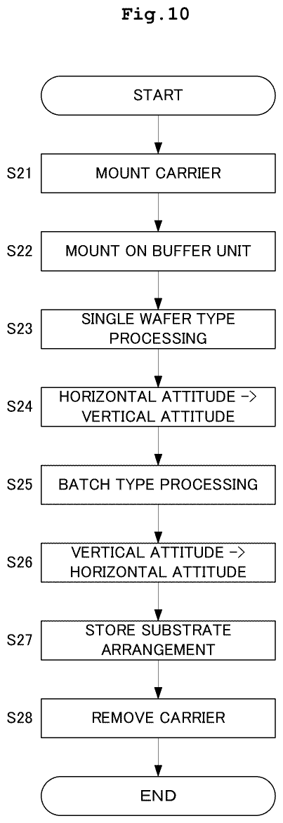

FIG. 10 is a flowchart describing the flow of the substrate processing of this example. In the substrate processing of this example, for example, each processing related to resist removal on the surface of the substrate W in the semiconductor device manufacturing process is performed. Hereinafter, the flow of the substrate processing will be specifically described along the flowchart.

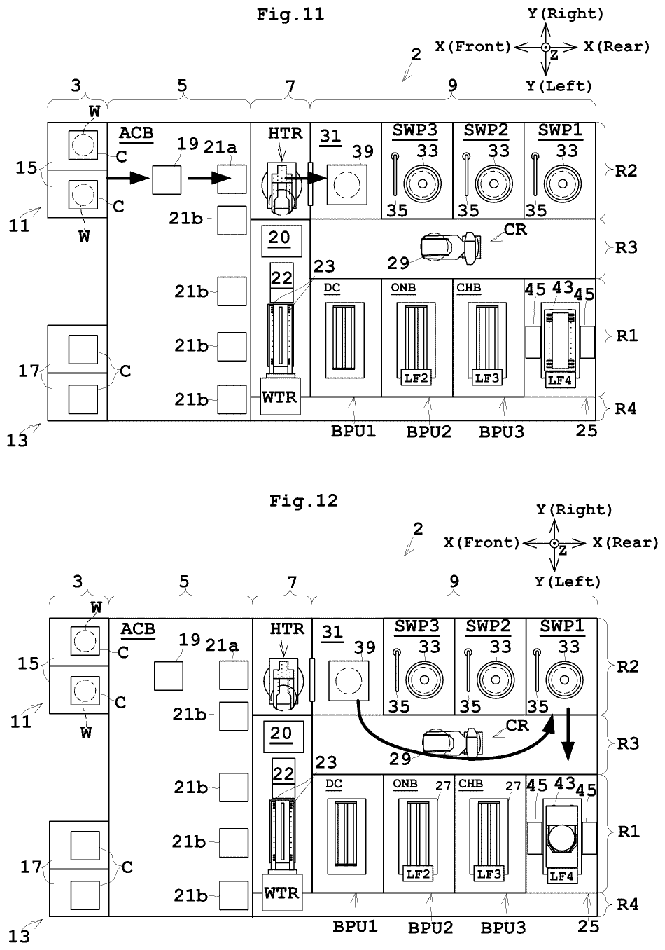

Step S21: An unprocessed substrate W is introduced into the substrate processing apparatus 2. Specifically, the carrier C storing the unprocessed substrates W is set on the mounting table 15 in the input unit 11 of the apparatus. Thereafter, the carrier C is taken into the apparatus from the input unit 11, and is mounted on the carrier mounting shelf 21a provided on the stocker block 5 by the transfer mechanism 19 (see FIG. 11).

Step S22: The lot is mounted on the buffer unit 31. Specifically, the first transfer mechanism HTR provided in the transfer block 7 collectively takes out the plurality of substrates W in the horizontal attitude from the carrier C. Then, the first transfer mechanism HTR mounts the lot on the buffer unit 31 while maintaining the attitude of the plurality of substrates W (see FIG. 11).

Step S23: Single wafer type processing is performed. Specifically, the substrates W in the horizontal attitude mounted on the buffer unit 31 are held by the center robot CR one by one and carried into any one of the single wafer liquid treatment chambers SWP1 to SWP3. FIG. 12 illustrates the movement of the substrate W in this step. In FIG. 12, the substrate W is transferred to the single wafer liquid treatment chamber SWP1, and processing related to resist removal is performed therein. The substrate W from which the resist has been removed is transferred to the underwater attitude changing unit 25 by the center robot CR. At this time, the underwater attitude changing unit 25 waits in an attitude capable of holding the substrate W in a horizontal attitude. Upon receiving the substrate W, the lifter LF4 of the underwater attitude changing unit 25 descends by the full pitch width to immerse the received substrate W in the water. The lifter LF4 repeats this operation every time the center robot CR carries in the substrate W. As a result, the substrates W in the horizontal attitude are arranged in the lifter LF4 in the vertical direction at a full pitch. As described above, the center robot CR transfers the plurality of substrates W mounted on the buffer unit 31 one by one to any one of the single wafer liquid treatment chambers SWP1 to SWP3 and the underwater attitude changing unit 25 in this order.

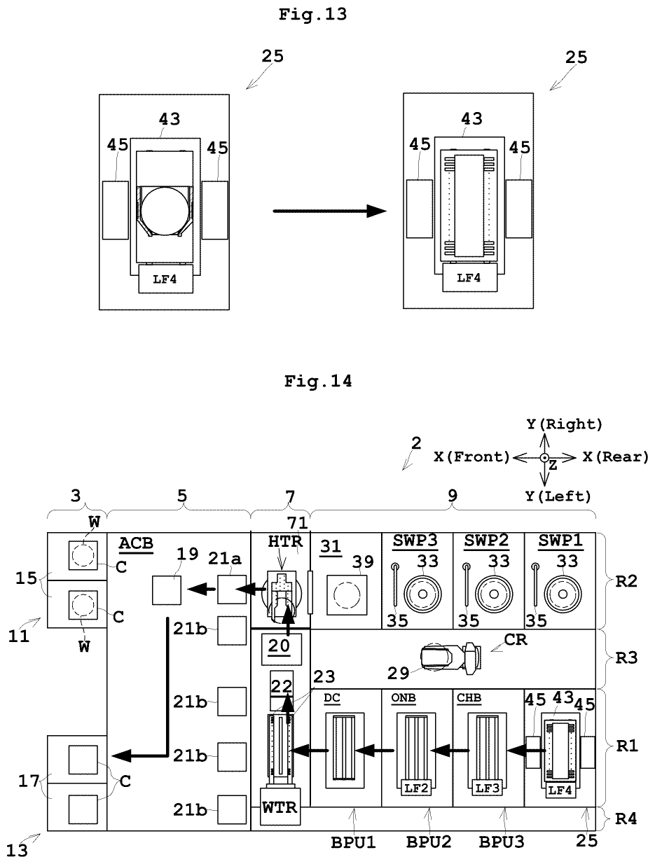

Step S24: The plurality of substrates W is collectively changed from the horizontal attitude to the vertical attitude. FIG. 13 illustrates a process related to attitude changing in the entire process of substrate processing. In the underwater attitude changing unit 25, the lifter LF4 at the handover position receives the substrates W one by one, and the lifter LF4 descends by a distance corresponding to the full pitch each time. Then, the substrates W are sequentially located below the liquid surface of the immersion tank 43. When such an operation is repeated, all of the substrates W constituting the lot are stocked in the immersion tank 43. After the substrates W for one lot are stocked in the immersion tank 43, the attitude changing mechanism 45 changes the attitude of the plurality of substrates W from the horizontal attitude to the vertical attitude by rotating the lot by 90° in water. As described above, the underwater attitude changing unit 25 collectively changes the attitude of the substrates W in the horizontal attitude received one by one into the vertical attitude. As described above, the underwater attitude changing unit 25 receives the substrates W in the horizontal attitude one by one. When the number of the received substrates W reaches a predetermined number (for example, 25), the plurality of substrates W in the horizontal attitude is collectively changed to the vertical attitude. All the substrates W subjected to attitude changing are stored in the same carrier C.

Step S25: Batch processing of a plurality of substrates W is performed. Specifically, the lot waiting in the underwater attitude changing unit 25 is collectively lifted in the vertical direction (Z direction) by the second transfer mechanism WTR, and then transferred in the front-rear direction (X direction). The plurality of substrates W in the vertical attitude is passed to the lifter LF3 of the third batch processing unit BPU3 in a state of being arranged in the width direction (Y direction). The lifter LF3 that receives the substrate W is at the handover position. In this manner, the lot is located above the liquid surface in the batch chemical solution treatment tank CHB. The lifter LF3 receiving the lot descends and immerses the lot in the batch chemical solution treatment tank CHB. In this manner, the chemical solution treatment for the lot is executed.

After the chemical solution treatment, the manner in which the cleaning treatment is performed on the lot in the batch rinse treatment tank ONB of the second batch processing unit BPU2 related to the rinse treatment is similar to that of the apparatus of the first embodiment.

When the cleaning treatment is completed, the lifter LF2 of the second batch processing unit BPU2 exposes the lot from the batch rinse treatment tank ONB above the liquid surface. The lot is then collectively lifted in the vertical direction (Z direction) by the second transfer mechanism WTR, and then transferred in the front-rear direction (X direction). The plurality of substrates W in the vertical attitude is transferred to the batch drying chamber DC in a state of being arranged in the width direction (Y direction), and is collectively subjected to a drying treatment (see FIG. 14). As described above, the second transfer mechanism WTR collectively receives the plurality of substrates W in the vertical attitude in the underwater attitude changing unit 25, and transfers the received plurality of substrates W to the third batch processing unit BPU3, the second batch processing unit BPU2, and the batch drying chamber DC in this order.

Step S26: After the drying treatment of the substrates W, the attitude is collectively changed from the vertical attitude to the horizontal attitude.

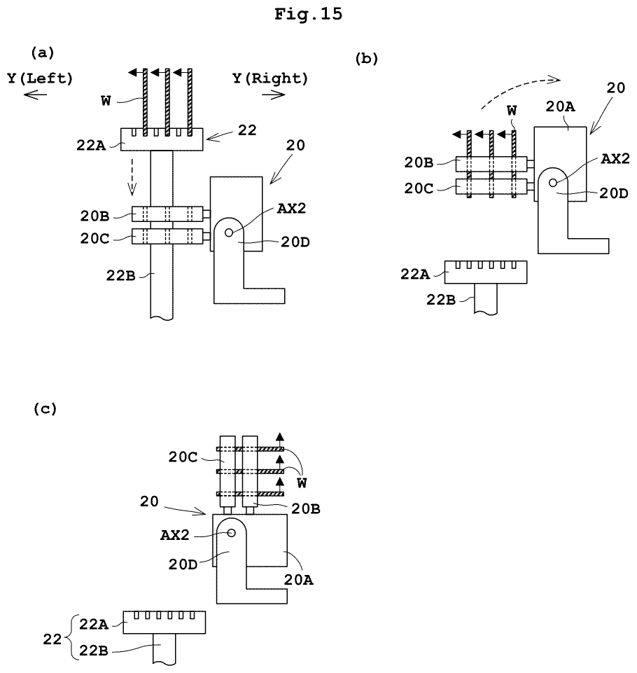

Specifically, the lot held in the batch drying chamber DC of the first batch processing unit BPU1 is collectively gripped by the second transfer mechanism WTR. Then, the lot is transferred to the substrate handover position P in the transfer block 7. The pusher mechanism 22 transfers the lot in the vertical attitude waiting at the substrate handover position P to the HVC attitude changing unit 20. As illustrated in FIG. 15, the HVC attitude changing unit 20 collectively changes the attitude of the plurality of substrates W from the vertical attitude to the horizontal attitude. That is, first, as illustrated in FIG. 15(a), the pusher 22A at the position immediately above descends and transfers the plurality of substrates W to the vertical holding unit 20C. Since the vertical holding unit 20C is provided with the V grooves, each of the substrates W held by the pusher 22A is clamped and held by the V grooves. When the pusher 22A further descends therefrom, as illustrated in FIG. 15(b), the plurality of substrates W is separated from the pusher 22A and held by the HVC attitude changing unit 20. When the support table 20A of the HVC attitude changing unit 20 is reversely rotated by 90° from this state, as illustrated in FIG. 15(c), the plurality of substrates W is held in the recess of the horizontal holding unit 20B of the HVC attitude changing unit 20 and is changed to the horizontal attitude.

Step S27: The plurality of substrates W changed to the horizontal attitude is collectively stored in the carrier C. Specifically, the lot in which the substrates W in the horizontal attitude held by the HVC attitude changing unit 20 are arranged is collectively received by the first transfer mechanism HTR and returned to the empty carrier C waiting on the carrier mounting shelf 21a in the stocker block 5. In the substrate processing of this example, since the carrier C and the lot inside the carrier C are associated with each other, the lot retrieved from the carrier C returns to the same carrier C after being subjected to various treatments. The carrier C storing the lot is moved to the dispensing unit 13 provided on the side wall of the carry-in/out block 3.

Step S28: The carrier C storing the plurality of substrates W is removed from the apparatus. In this manner, the substrate processing by the substrate processing apparatus 2 according to the present example ends.

As described above, according to the present example, the buffer unit 31 to and from which both the first transfer mechanism HTR and the center robot CR can hand over and receive the substrate(s) W is provided in the single wafer processing region R2. Therefore, the first transfer mechanism HTR can collectively hand over the substrates W to the single wafer processing region R2 via the buffer unit 31. Further, the center robot CR can hand over the substrates W taken out one by one from the buffer unit 31 to the single wafer liquid treatment chambers SWP1 to SWP3. With this configuration, the first transfer mechanism HTR collectively takes the substrates W in and out of the carrier C. Therefore, the potential of the first transfer mechanism HTR is drawn out, and the substrate processing apparatus 2 having a high throughput can be provided. Further, in the present example, the plurality of substrates W subjected to the single wafer processing is transferred in a direction away from the transfer block 7 when moving toward the underwater attitude changing unit 25. Then, the plurality of substrates W whose attitude has been changed by the underwater attitude changing unit 25 is transferred in a direction approaching the transfer block 7 when the batch processing is performed. As described above, with a configuration to perform the single wafer processing while the substrates W are transferred in the processing block 9 in the direction away from the transfer block 7, and perform the batch processing while the substrates W are transferred so as to approach the transfer block 7, the reciprocation of the substrate W is performed only once, and a substrate processing apparatus having a short transfer distance and a high throughput can be provided.

The present invention is not limited to the above-described configuration, and the following modifications can be made.

### <Modification 1>

For example, 50 substrates W arranged at a half pitch in the first embodiment are arranged in a face-to-back manner in which the device surfaces face the same direction, but the present invention is not limited to this configuration, and for example, 50 substrates W may be arranged in a face-to-face manner. An advantage of arranging 50 substrates W in a face-to-face manner is that the device surface of the first substrate W in the lot can be oriented toward the second substrate W, and the device surface of the 50th substrate W in the lot can be oriented toward the 49th substrate W. Thus, when the device surfaces of the substrates W at both ends of the lot are directed inward, the lot is transferred in a state where the device surfaces of the substrates W are protected. Therefore, if the substrates W are arranged in a face-to-face manner, a desired circuit pattern can be reliably formed on the substrates W.

The face-to-face lot is formed by the HVC attitude changing unit 20 and the pusher mechanism 22 in the transfer block 7. In order to form the lot, first, for example, 25 first substrates W1 in a horizontal attitude are brought into a vertical attitude by the HVC attitude changing unit 20. Then, the first substrates W1 whose attitude has been changed are picked up by the pusher 22A. Thereafter, the first substrates W1 are horizontally reversed, and the device surfaces of the first substrates W1 are reversed. Then, for example, 25 second substrates W2 in the horizontal attitude are brought into the vertical attitude by the HVC attitude changing unit 20. Finally, the pusher 22A picks up the second substrates W2 to complete the lot. Thus, while the first substrates W1 are reversed and incorporated into the lot, the second substrates W2 are incorporated into the lot without being reversed. Therefore, the orientations of the device surfaces are different between the first substrates W1 and the second substrates W2. Since the first substrates W1 and the second substrates W2 are alternately arranged, the generated lot is in a face-to-face manner in which the device surfaces of the adjacent substrates W face each other.

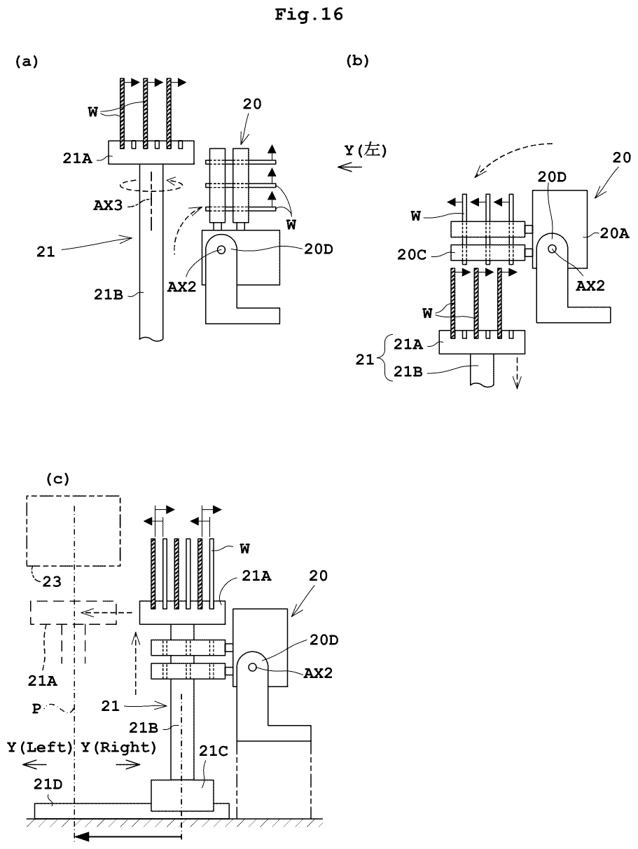

Hereinafter, each process relating to lot formation will be specifically described with reference to FIG. 16. In the lot forming process, operations up to an operation in which the pusher 22A picks up the first substrates W1 are similar to those in FIGS. 3(a) to 3(c) in the first embodiment, and thus the description thereof is omitted. FIG. 16 illustrates the subsequent operation. FIG. 16(a) is a view corresponding to FIG. 3(d) described above, and illustrates a state in which the pusher 22A is not shifted in the Y direction as in the first embodiment, but is rotated by 180° instead. With this operation, all the device surfaces of the first substrates W1 that have been oriented in the left direction are oriented in the right direction. Further, at this time, the phase of the arrangement of the first substrates W1 is shifted by a half pitch. In order to implement such a shift operation, the rotation center of the pusher 22A is slightly shifted from the center in the arrangement of the first substrates W1 in the arrangement direction (by a half width of the half pitch width).

FIG. 16(b) is a view corresponding to FIG. 3(e) described above, and illustrates a state when the support table 20A holding the second substrates W2 is rotated by 90°. At this time, since the device surfaces of the second substrates W2 in the horizontal attitude face upward, all the device surfaces face leftward.

FIG. 16(c) is a view corresponding to FIG. 3(f) described above, and illustrates a state when the pusher 22A moves to the position immediately above again. Since the first substrates W1 are rotated by 180° to shift the arrangement phase by the half pitch, the second substrates W2 clamped by the vertical holding unit 20C are accommodated in the empty grooves interposed between the first substrates W1 on the upper surface of the pusher 22A without interfering with the first substrates W1, similarly to the case of FIG. 3(f). In this manner, the face-to-face lot in which the first substrates W1 having the device surfaces facing the right direction and the second substrates W2 having the device surfaces facing the left direction are alternately arranged is formed. The pusher mechanism 22 can transfer the formed lot to the substrate handover position P.

In the case of the first embodiment, when the center robot CR accesses the underwater attitude changing unit 25, the underwater attitude changing unit 25 collectively rotates the substrates W by 180 degrees each time. Thus, when the single wafer type processing is performed, the surface on which the circuit pattern is formed is directed upward on any of the substrates W.

### <Modification 2>

The underwater attitude changing unit 25 according to the present invention changes the attitude of the substrate array in water, but the present invention is not limited to this configuration. The attitude changing unit may be configured to change the attitude in the air, or the attitude changing unit may be configured to include a shower for spraying a liquid such as pure water to the substrate W.

### <Modification 3>

In the apparatus of the present invention, the center robot CR having a hand including a pair of arms is provided, but instead of this, the center robot CR having two hands may be provided. The two hands are arranged vertically, and the upper hand may be used for transferring a substrate after the drying treatment, and the lower hand may be used for transferring a substrate before the drying treatment. With such a configuration, since the substrate W after the drying treatment is not gripped by a wet hand, the dry state of the substrate W can be reliably maintained. Further, by arranging the hand for transferring the substrate W after the drying treatment above the hand for transferring the substrate W before the drying treatment, the liquid adhering to the hand for transferring the substrate before the drying treatment does not drip on the hand for transferring the substrate after the drying treatment, and the dry state of the hand for transferring the substrate after the drying treatment can be reliably maintained.

### <Modification 4>

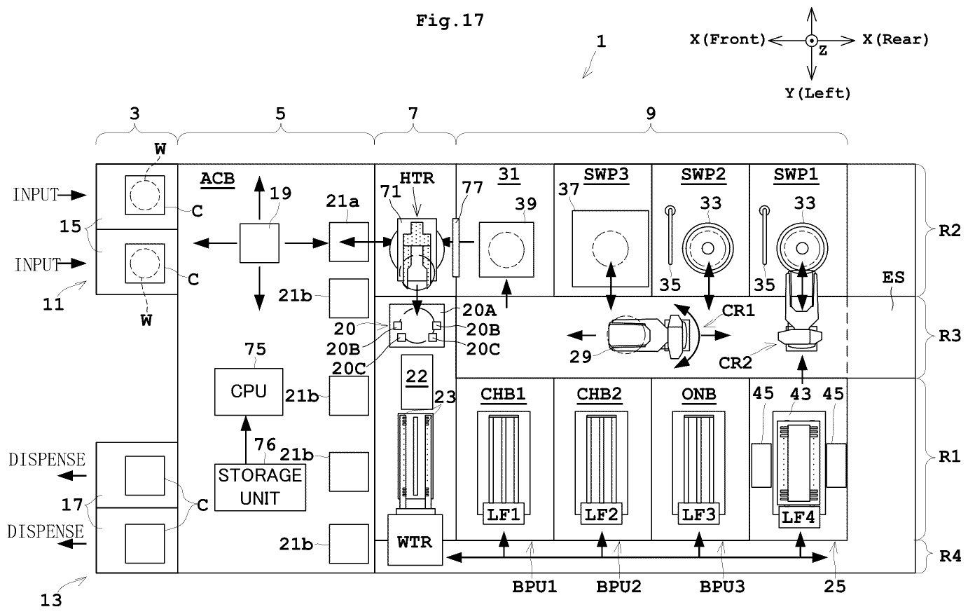

The above-described apparatus is configured to include one center robot CR, but may be configured to include a plurality of center robots CR1 and CR2 movable in the front-rear direction (X direction) as illustrated in FIG. 17. In this case, in the center robot, a retreat region ES for retreating the center robot CR2 located on the far side as viewed from the transfer block 7 may be provided on the far side of the single substrate transfer region R3 in the processing block 9. With such a configuration, the center robot CR1 positioned on the near side as viewed from the transfer block 7 can reliably access the underwater attitude changing unit 25 and the single wafer liquid treatment chamber SWP1. That is, when the center robot CR2 located on the far side as viewed from the transfer block 7 is retracted to the retreat region ES, the center robot CR1 can be reliably positioned up to the underwater attitude changing unit 25 and the single wafer liquid treatment chamber SWP1. Since the center robot CR2 at this time is further located on the far side than the underwater attitude changing unit 25 and the like, it does not hinder the operation of the center robot CR1. Further, one of the center robots CR1 and CR2 may be used for transferring the substrate before the drying treatment, and the other may be used for transferring the substrate after the drying treatment. With this configuration, since the robot that transfers the substrate W after the drying treatment is provided separately from the robot that transfers the substrate W before the drying treatment, the substrate W before the drying treatment and the substrate W after the drying treatment can be transferred simultaneously, so that the throughput of the substrate processing apparatus is improved. Further, since the robot that transfers the substrate W after the drying treatment does not grip the wet substrate W before the drying treatment, the robot that transfers the substrate W after the drying treatment does not transfer the substrate W after the drying treatment in a wet state. Therefore, with such a configuration, it is possible to provide a substrate processing apparatus that reliably maintains the dry state of the substrate W.

### REFERENCE SIGNS LIST

5 stocker block
7 transfer block
9 processing block
20 HVC attitude changing unit (first attitude changing mechanism)
21a mounting shelf (carrier mounting shelf)
25 underwater attitude changing unit (second attitude changing mechanism)
31 buffer unit (substrate mounting unit)
C carrier
CHB batch chemical solution treatment tank (batch processing tank)
CHB1 batch chemical solution treatment tank (batch processing tank)
CHB2 batch chemical solution treatment tank (batch processing tank)
CR center robot (single substrate transfer mechanism)
DC batch drying chamber
HTR first transfer mechanism (substrate handling mechanism)
ONB batch rinse treatment tank (batch processing tank)
P substrate handover position
R1 batch processing region
R2 single wafer processing region
R3 single substrate transfer region
R4 batch substrate transfer region
SWP3 single wafer drying treatment chamber (single wafer processing chamber)
SWP1 single wafer liquid treatment chamber (single wafer processing chamber)
SWP2 single wafer liquid treatment chamber (single wafer processing chamber)
W substrate
WTR second transfer mechanism (batch substrate transfer mechanism)

1. A substrate processing apparatus that continuously performs batch processing of collectively processing a plurality of substrates and single wafer processing of processing substrates one by one, the substrate processing apparatus comprising:
a stocker block;
a transfer block adjacent to the stocker block; and
a processing block adjacent to the transfer block,
wherein the stocker block includes at least one carrier mounting shelf for accommodating at least one carrier that stores a plurality of substrates in a horizontal attitude at predetermined intervals in a vertical direction, in order to take out and store the substrates, the carrier being mounted on the carrier mounting shelf for taking in and out the substrates from the carrier,
the transfer block includes:
a substrate handling mechanism that collectively takes out and stores a plurality of substrates with respect to the carrier mounted on the carrier mounting shelf; and
a first attitude changing mechanism that collectively changes an attitude of a plurality of substrates between a horizontal attitude and a vertical attitude,
the processing block includes:
a batch processing region having one end side adjacent to the transfer block and another end side extending in a direction away from the transfer block;
a single wafer processing region having one end side adjacent to the transfer block and another end side extending in the direction away from the transfer block;
a single substrate transfer region interposed between the batch processing region and the single wafer processing region, and having one end adjacent to the transfer block and another end side extending in the direction away from the transfer block; and
a batch substrate transfer region provided along the batch processing region, and having one end side extending to the transfer block and another end side extending in the direction away from the transfer block, and
in the batch processing region, a plurality of batch processing tanks that collectively subjects a plurality of substrates to an immersion treatment is arranged in a direction in which the region extends, and a second attitude changing mechanism that collectively changes an attitude of the plurality of substrates between a vertical attitude and a horizontal attitude is provided at a position farthest from the transfer block,
in the single wafer processing region, a plurality of single wafer processing chambers that processes substrates one by one is arranged in a direction in which the region extends, and a substrate mounting unit that mounts a plurality of substrates in a horizontal attitude at same predetermined intervals as the predetermined intervals of the carrier in a vertical direction is provided at a position closest to the transfer block,
in the single substrate transfer region, a single substrate transfer mechanism that transfers a substrate among the second attitude changing mechanism, the single wafer processing chamber, and the substrate mounting unit is provided,
in the batch substrate transfer region, a batch substrate transfer mechanism that collectively transfers a plurality of substrates among a substrate handover position defined in the transfer block, the batch processing tanks, and the second attitude changing mechanism is provided, and
the substrate handling mechanism of the transfer block is further configured to be able to collectively transfer a plurality of substrates to and from the substrate mounting unit in the single wafer processing region.

2. The substrate processing apparatus according to claim 1, wherein
the batch processing region includes a batch chemical solution treatment tank that stores a chemical solution for collectively performing a chemical solution treatment on a plurality of substrates, and a batch rinse treatment tank that stores a rinse solution for collectively performing a rinse treatment on a plurality of substrates subjected to the chemical solution treatment,
the batch chemical solution treatment tank is located closer to the transfer block than the batch rinse treatment tank,
the single wafer processing region includes a single wafer liquid treatment chamber for liquid treatment of substrates one by one, and a single wafer drying treatment chamber for drying the substrates subjected to liquid treatment one by one,
the single wafer drying treatment chamber is located closer to the transfer block than the single wafer liquid treatment chamber,
in the transfer block,
the substrate handling mechanism collectively takes out a plurality of substrates from the carrier, and
the first attitude changing mechanism changes an attitude of the plurality of substrates taken out from a horizontal attitude to a vertical attitude,
in the processing block,
the batch substrate transfer mechanism collectively receives a plurality of substrates in a vertical attitude at the substrate handover position of the transfer block and transfers the received plurality of substrates to the batch chemical solution treatment tank, the batch rinse treatment tank, and the second attitude changing mechanism in this order,
the second attitude changing mechanism changes an attitude of the received plurality of substrates in the vertical attitude to a horizontal attitude, and
the single substrate transfer mechanism transfers the substrates changed to the horizontal attitude by the second attitude changing mechanism one by one to the single wafer liquid treatment chamber, the single wafer drying treatment chamber, and the substrate mounting unit in this order, and
in the transfer block,
when a plurality of substrates is mounted on the substrate mounting unit in the processing block, the substrate handling mechanism collectively takes out the plurality of substrates from the substrate mounting unit and collectively stores the plurality of substrates taken out in the carrier.

3. The substrate processing apparatus according to claim 1, wherein
the single wafer processing region includes a single wafer liquid treatment chamber for liquid treatment of substrates one by one,
the batch processing region includes a batch chemical solution treatment tank that stores a chemical solution for collectively performing a chemical solution treatment on a plurality of substrates, a batch rinse treatment tank that stores a rinse solution for collectively performing a rinse treatment on a plurality of substrates subjected to the chemical solution treatment, and a batch drying chamber that collectively performs a drying treatment of the plurality of substrates subjected to the rinse treatment,
the batch drying chamber is located closer to the transfer block than the batch rinse treatment tank,
the batch rinse treatment tank is located closer to the transfer block than the batch chemical solution treatment tank,
in the transfer block,
the substrate handling mechanism collectively takes out a plurality of substrates from the carrier and mounts the substrates on the substrate mounting unit in the processing block,
in the processing block,
the single substrate transfer mechanism transfers a plurality of substrates mounted on the substrate mounting unit one by one to the single wafer liquid treatment chamber and the second attitude changing mechanism in this order,
the second attitude changing mechanism changes an attitude of a plurality of substrates in a horizontal attitude to a vertical attitude when the plurality of substrates in the horizontal attitude is received, and
the batch substrate transfer mechanism collectively receives the plurality of substrates in the vertical attitude in the second attitude changing mechanism and transfers the received plurality of substrates to the batch chemical solution treatment tank, the batch rinse treatment tank, the batch drying chamber, and the substrate handover position in the transfer block, and
in the transfer block,
the first attitude changing mechanism changes an attitude of a plurality of substrates received at the substrate handover position from a vertical attitude to a horizontal attitude, and
the substrate handling mechanism collectively stores the plurality of substrates in the horizontal attitude in the carrier.

4. The substrate processing apparatus according to claim 2, wherein the single wafer drying treatment chamber dries the substrate with a supercritical fluid.

5. The substrate processing apparatus according to claim 1, wherein the single substrate transfer mechanism includes a first hand that transfers a substrate before the drying treatment, and a second hand that transfers a substrate after the drying treatment, the second hand being provided above the first hand.

6. The substrate processing apparatus according to claim 1, wherein the single substrate transfer mechanism includes a first robot that transfers a substrate before the drying treatment, and a second robot that transfers a substrate after the drying treatment.
